(19) United States
(12) Patent Application Publication
(10) Pub. No.: US 2024/0237524 A1
(43) Pub. Date: Jul. 11, 2024

(54) ORGANIC LIGHT EMITTING DIODE

(71) Applicant: LG Display Co., Ltd., Seoul (KR)

(72) Inventors: Yo-Sub LEE, Paju-si (KR); Jeong-Eun WON, Paju-si (KR); Chun-Ki KIM, Paju-si (KR)

(73) Assignee: LG Display Co., Ltd., Seoul (KR)

(21) Appl. No.: 18/381,049

(22) Filed: Oct. 17, 2023

(30) Foreign Application Priority Data
Dec. 27, 2022 (KR) 10-2022-0186243

(51) Int. Cl. H10K 85/60; H10K 50/11; H10K 50/15; H10K 50/16

(52) U.S. Cl. CPC H10K 85/6572; H10K 50/11; H10K 50/15; H10K 50/16; H10K 85/633; H10K 85/6574

(57) ABSTRACT

An organic light emitting diode (OLED) and an organic light emitting device comprising the OLED (e.g., a display device or a lighting device) are described. An emissive layer disposed between two electrodes comprises an exciton control layer between a red emitting material layer and a green emitting material layer. Exciton recombination zone is distributed uniformly within the entire area of an emitting material layer and holes and electrons can be injected into the emitting material layer in balance. The degradations of the luminous materials and/or charge transporting materials caused by quenched excitons as non-emission can be minimized. The luminous lifespan of the OLED can be improved, while maintaining luminous efficiency.

### CROSS-REFERENCE TO RELATED APPLICATIONS

This application claims priority, under 35 U.S.C. § 119(a), to Korean Patent Application No. 10-2022-0186243, filed in the Republic of Korea on Dec. 27, 2022, the entire contents of which are hereby expressly incorporated by reference into the present application.

### BACKGROUND

### Technical Field

The present disclosure relates to an organic light emitting diode (OLED), and more particularly to, an OLED having improved luminous efficiency and/or luminous lifespan, as well as to an organic light emitting device including the OLED (e.g., a display device or a lighting device).

### Discussion of Related Art

As demand increases for flat panel display devices that occupy a smaller space, an organic light emitting diode (OLED) has been a focus of recent research and development. An OLED has certain advantages over a liquid crystal display device (LCD). For instance, an OLED can be formed as a thin organic film less than 2000 Å, and the electrode configurations can implement unidirectional or bidirectional images. Also, the OLED can be formed on a flexible transparent substrate, e.g., such as a plastic substrate, so that a flexible or a foldable display device can be realized with ease using the OLED. In addition, the OLED can be driven at a lower voltage and the OLED has advantageous high color purity compared to the LCD.

However, there remains a need to develop OLEDs and devices thereof that have improved luminous efficiency and luminous lifespan. Since fluorescent materials use only singlet excitons in the luminous process, they can suffer from low luminous efficiency. Meanwhile, phosphorescent materials can show high luminous efficiency since they use triplet exciton as well as singlet excitons in the luminous process. But, examples of such phosphorescent material include metal complexes, which can have luminous lifespans that are too short for commercial use. As such, there remains a need to develop an OLED with sufficient luminous efficiency and luminous lifespan.

### SUMMARY OF THE DISCLOSURE

Accordingly, some embodiments of the present disclosure are directed to an organic light emitting diode and an organic light emitting device that substantially obviate one or more of the problems due to the limitations and disadvantages of the related art.

An aspect of the present disclosure is to provide an organic light emitting diode that can implement low power consumption and can have beneficial luminous efficiency and luminous lifespan, as well as an organic light emitting device comprising the diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode that comprises a first electrode; a second electrode facing the first electrode; and an emissive layer disposed between the first and second electrode, and comprising an emitting material layer, wherein the emitting material layer comprises: a red emitting material layer; a green emitting material layer disposed between the red emitting material layer and the second electrode; and an exciton control layer disposed between the red emitting material layer and the green emitting material layer, and wherein the exciton control layer comprises at least one of a first compound having the following structure of Chemical Formula 1 and a second compound having the following structure of Chemical Formula 3:

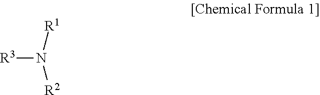

wherein, in Chemical Formula 1,
each of R¹, R² and R³ is independently an unsubstituted or substituted C₆-C₃₀ aryl group or an unsubstituted or substituted C₃-C₃₀ hetero aryl group,

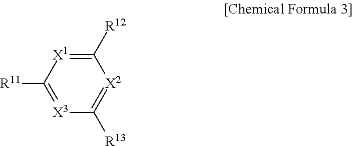

wherein, in Chemical Formula 3,
each of R¹¹, R¹² and R¹³ is independently hydrogen, an unsubstituted or substituted C₆-C₃₀ aryl group or an unsubstituted or substituted C₃-C₃₀ hetero aryl group, where at least one of R¹¹, R¹² and R¹³ has a moiety of the following structure of Chemical Formula 3A;
each of X¹, X² and X³ is independently CR¹⁴ or N, where at least two of X¹, X² and X³ is N (e.g., a diazine such as a pyrimidine, a triazine such as 1,3,5-triazine, etc.);
R¹⁴ is hydrogen, and unsubstituted or substituted C₆-C₃₀ aryl group or an unsubstituted or substituted C₃-C₃₀ hetero aryl group, or
optionally,
adjacent R¹¹ and R¹⁴, adjacent R¹² and R¹⁴ and/or adjacent R¹³ and R¹⁴ are further linked together to form an unsubstituted or substituted C₆-C₂₀ aromatic ring,

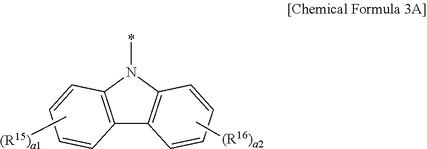

wherein, in Chemical Formula 3A,
each of R¹⁵ and R¹⁶ is independently an unsubstituted or substituted C₆-C₃₀ aryl group or an unsubstituted or substituted C₃-C₃₀ hetero aryl group, where each R¹⁵ is identical to or different from each other when a1 is 2, 3 or 4, and each R¹⁶ is identical to or different from each other when a2 is 2, 3 or 4, or
optionally,
two adjacent R¹⁵ when a1 is 2, 3 or 4, and/or
two adjacent R¹⁶ when a2 is 2, 3 or 4
are further linked together to form an unsubstituted or substituted C₆-C₂₀ aromatic ring;
each of a1 and a2 is independently 0, 1, 2, 3 or 4, where at least one of a1 and a2 is not 0; and
the asterisk indicates a link to a ring of Chemical Formula 3.

The exciton control layer can comprise the first compound and/or the second compound. In certain aspects, the exciton control layer comprises both the first compound and the second compound.

In an embodiment, the organic light emitting diode may comprise a first electrode; a second electrode facing the first electrode; and an emissive layer disposed between the first and second electrode, and comprising an emitting material layer, wherein the emitting material layer comprises: a red emitting material layer; a green emitting material layer disposed between the red emitting material layer and the second electrode; and an exciton control layer disposed between the red emitting material layer and the green emitting material layer, and wherein the exciton control layer comprises a first compound having the following structure of Chemical Formula 1 and/or a second compound having the following structure of Chemical Formula 3, where in Chemical Formula 1, each of R¹, R² and R³ is independently an unsubstituted or substituted phenyl, biphenyl,

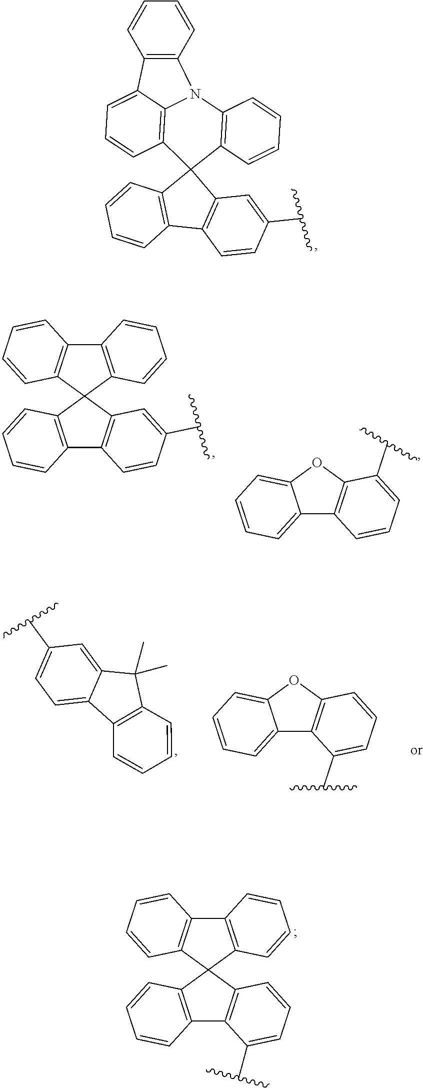

and in Chemical Formula 3, each of R¹¹, R¹² and R¹³ is independently an unsubstituted or substituted phenyl, biphenyl,

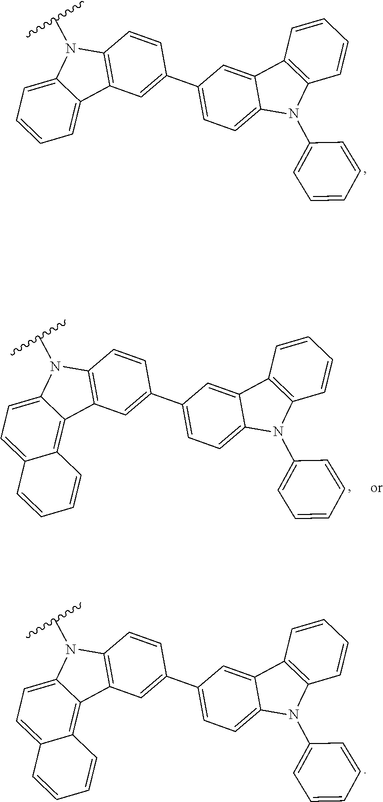 [SMILES: *n1c2ccccc2c2cc(-c3ccc4c(c3)c3ccccc3n4-c3ccccc3)ccc21 ; *n1c2ccc(-c3ccc4c(c3)c3ccccc3n4-c3ccccc3)cc2c2c3ccccc3ccc21 ; *n1c2ccc(-c3ccc4c(c3)c3ccccc3n4-c3ccccc3)cc2c2c3ccccc3ccc21]

In an embodiment, the first compound can comprise at least one of compounds 1-1 to 1-9 as described herein, and the second compound can comprise at least one of compounds 2-1 to 2-9 as described herein.

A difference between a highest occupied molecular orbital (HOMO) energy level of the first compound and a HOMO energy level of the second compound can be equal to or less than about 0.2 eV, for example, about 0.15 eV., 0.13 eV, or 0.10 eV. A difference between a HOMO energy level of the first compound and a HOMO energy level of the second compound can be equal to or more than about 0.01 eV, for example, about 0.03 eV, 0.05 eV, or 0.07 eV

The first compound and the second compound in the exciton control layer can be mixed with a weight ratio in a range between about 7:3 and about 3:7. In certain aspects, the first compound and the second compound in the exciton control layer can be mixed with a weight ratio in a range between about 6:4, or about 5:5.

In one embodiment, the emissive layer can further comprise an electron transport layer disposed between the first electrode and the emitting material layer; and a hole transport layer disposed between the emitting material layer and the second electrode.

In another embodiment, the emissive layer can comprise a first emitting part disposed between the first electrode and the second electrode, and comprising a first emitting material layer; a second emitting part disposed between the first emitting part and the second electrode, and comprising a second emitting material layer; and a first charge generation layer disposed between the first emitting part and the second emitting part.

The second emitting part can comprise the red emitting material layer, the green emitting material layer and the exciton control layer.

In another embodiment, the emissive layer can further comprise a third emitting part disposed between the second emitting part and the second electrode, and comprising a third emitting material layer; and a second charge generation layer disposed between the second emitting part and the third emitting part. In an embodiment, the third emitting material layer can comprise a second blue emitting material layer.

In another aspect, the present disclosure provides an organic light emitting diode that comprises a first electrode; a second electrode facing the first electrode; and an emissive layer disposed between the first electrode and the second electrode, wherein the emissive layer comprises a first emitting part disposed between the first electrode and the second electrode, and comprising a first emitting material layer; a second emitting part disposed between the first emitting part and the second electrode, and comprising a second emitting material layer; and a first charge generation layer disposed between the first emitting part and the second emitting part, wherein the first emitting part comprises a first blue emitting material layer, wherein the second emitting part comprises a red emitting material layer disposed between the first charge generation layer and the second electrode; a green emitting material layer disposed between the red emitting material layer and the second electrode; and an exciton control layer disposed between the red emitting material layer and the green emitting material layer, and the exciton control layer comprises at least one of the first compound having the structure of Chemical Formula 1 and the second compound having the structure of Chemical Formula 3.

For example, the second emitting part can further comprise an electron transport layer disposed between the first charge generation layer and the second emitting material layer; and a hole transport layer disposed between the second emitting material layer and the second electrode.

In one or more embodiments, the OLED comprises the exciton control layer disposed between the red emitting material layer and the green emitting material layer that can control charge transportations and/or exciton emission area.

Exciton recombination zone can be distributed uniformly in the entire area of the emitting material layer comprising the red emitting material layer and the green emitting material layer and holes and electrons can be injected into the emitting material layer in balance by the exciton control layer. As the exciton recombination zone is distributed uniformly within the emitting material layer, the amount of quenched as non-emission excitons can be minimized. The degradations of the luminous materials and the charge transporting materials by the quenched excitons can be prevented. Accordingly, the OLED and the organic light emitting device with improved luminous lifespan together with maintaining luminous efficiency can be realized.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device according to one or more embodiments of the present disclosure.

FIG. 2 illustrates a cross-sectional view of an organic light emitting display device as an example of an organic light emitting device in accordance with one or more embodiments of the present disclosure.

FIG. 3 illustrates a cross-sectional view of an organic light emitting diode having a normal structure in accordance with one or more embodiments of the present disclosure.

FIG. 4 illustrates a cross-sectional view of an organic light emitting diode having an inverted structure in accordance with one or more embodiments of the present disclosure.

FIG. 5 illustrates a schematic diagram showing exciton recombination zone in a red emitting material layer and a green emitting material layer in a conventional organic light emitting diode.

FIG. 6 illustrates a schematic diagram showing exciton recombination zone in a red emitting material layer and a green emitting material layer in accordance with one or more embodiments of the present disclosure.

FIG. 7 illustrates a cross-sectional view of an organic light emitting display device in accordance with one or more embodiments of the present disclosure.

FIG. 8 illustrates a cross-sectional view of an organic light emitting diode having a normal structure and a tandem structure of multiple emitting parts in accordance with one or more embodiments of the present disclosure.

FIG. 9 illustrates a cross-sectional view of an organic light emitting diode having an inverted structure and a tandem structure of multiple emitting parts in accordance with one or more embodiments of the present disclosure.

FIGS. 10 to 13 illustrate measurement results of EQE (external quantum efficiency), electroluminescence (EL) intensity, luminous lifespan of red light and luminous lifespan of green light fabricated in Examples in the following and Comparative Example.

FIGS. 14 to 17 illustrate measurement results of EQE (external quantum efficiency), electroluminescence (EL) intensity, luminous lifespan of red light and luminous lifespan of green light fabricated in another Examples in the following and Comparative Example.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. In the following description, when a detailed description of well-known functions or configurations related to this document is determined to unnecessarily cloud a gist of the inventive concept, the detailed description thereof will be or can be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations are selected only for convenience of writing the specification and can be thus different from those used in actual products. Further, all the components of each organic light emitting diode (OLED) and each organic light emitting device (e.g., display device, illumination device, etc.) using the OLED according to all embodiments of the present disclosure are operatively coupled and configured.

The present disclosure relates to an organic light emitting diode and/or an organic light emitting device that includes an exciton control layer, which can control or regulate charge transportations and/or exciton recombination zone, between two emitting material layer emitting different colors so as to improve the luminous properties thereof.

As an example, in one or more embodiments of the present disclosure, the emissive layer in the OLED can be applied into an organic light emitting diode with a single emitting unit in a red pixel region and/or a blue pixel region. Alternatively, the emissive layer can be applied into an organic light emitting diode where multiple emitting parts are stacked to form a tandem-structure. The organic light emitting diode can be applied to an organic light emitting device such as an organic light emitting display device or an organic light emitting illumination device.

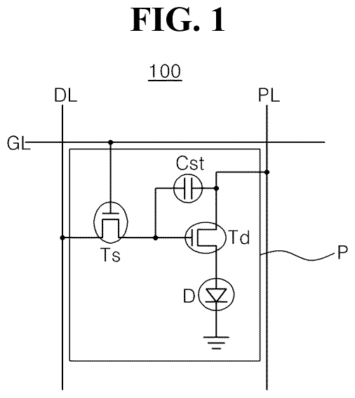

FIG. 1 illustrates a schematic circuit diagram of an organic light emitting display device in accordance with one or more embodiments of the present disclosure.

As illustrated in FIG. 1, a gate line GL, a data line DL and a power line PL, each of which crosses each other to define a pixel region P, are provided in the organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region, but other variations are possible. For instance, the pixel region P can include a red pixel region, a green pixel region, a blue pixel region and a white pixel region. The organic light emitting display device 100 includes a plurality of such pixel regions P which can be arranged in a matrix configuration or other configurations. The organic light emitting display device can further include other components such as a timing controller, a scan driver, a data driver, a power source, etc., and can be a flexible, bendable, or wearable device, which can include a touch function. However, embodiments of the present disclosure are not limited to such examples.

In each pixel region P, the switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

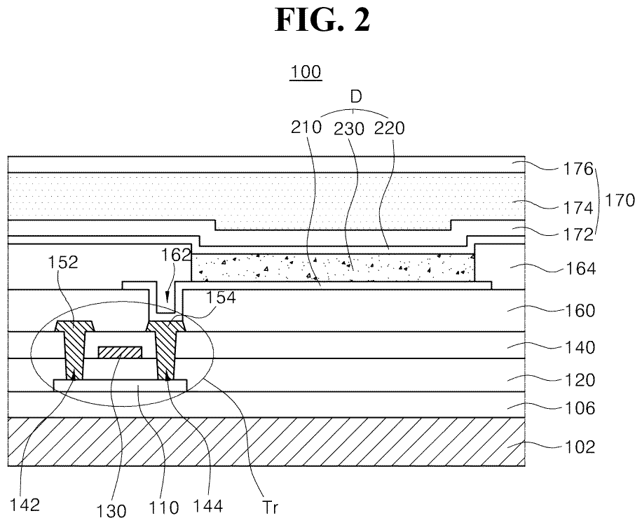

The driving thin film transistor Td is turned on by the data signal applied to a gate electrode 130 (FIG. 2) so that a current proportional to the data signal is supplied from the power line PL to the organic light emitting diode D through the driving thin film transistor Td. Then the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an embodiment of the present disclosure. The pixel circuit configuration of FIG. 1 can be used in the display device of FIG. 2 or other figures of the present application.

As illustrated in FIG. 2, the organic light emitting display device 100 includes a substrate 102, a thin-film transistor Tr on the substrate 102, and an organic light emitting diode D connected to the thin film transistor Tr. As an example, the substrate 102 can include a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region. For example, the organic light emitting diode D can be disposed in the red pixel region and/or the green pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ) or silicon nitride (SiNₓ), or an organic insulating material such as benzocyclobutene or photo-acryl.

The interlayer insulating layer 140 has first semiconductor layer contact hole 142 and a second semiconductor layer contact hole 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively. In certain embodiments, the designation of the source and drain electrodes 152 and 154 can be switched with each other depending on the type and configuration of a transistor.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole (or a contact hole) 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed in each pixel region P. The first electrode 210 can be an anode or a cathode and include conductive material having relatively high work function value. For example, the first electrode 210 can include a transparent conductive oxide (TCO). For example, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

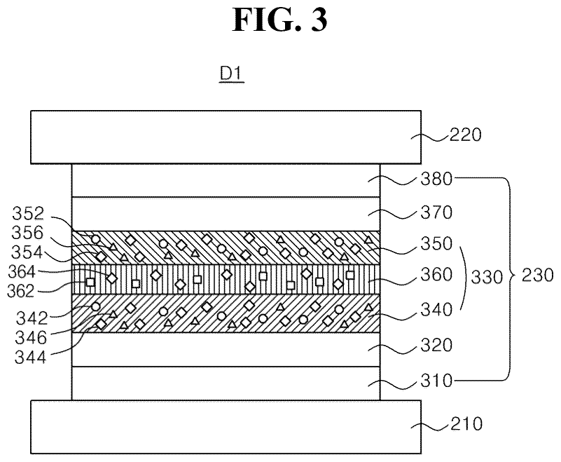

The emissive layer 230 is disposed on the first electrode 210. In one embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3).

In one embodiment, the emissive layer 230 can have a single emitting part. Alternatively, the emissive layer 230 can have multiple emitting parts to form a tandem structure. For example, the emissive layer 230 can be applied to an organic light emitting diode having a single emissive layer disposed in each of the red pixel region, the green pixel region and the blue pixel region, respectively. Alternatively, the emissive layer 230 can be applied to an organic light emitting diode of a tandem structure stacked multiple emitting parts. The emissive layer 230 can include an exciton control layer between plural emitting material layers that emit different colors.

The second electrode 220 is disposed on the substrate 102 above which the emissive layer 230 is disposed. The second electrode 220 can be disposed on the entire display area. The second electrode 220 can include a conductive material with a relatively low work function value compared to the first electrode 210, and can be a cathode providing electrons or an anode proving holes. For example, the second electrode 220 can include highly reflective material such as aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

A polarizing plate can be attached onto the encapsulation film 170 to reduce reflection of external light. For example, the polarizing plate can be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window can have a flexible property, thus the organic light emitting display device 100 can be a flexible display device.

The OLED D according to one embodiment is described in more detail in FIG. 3. FIG. 3 illustrates a schematic cross-sectional view of an organic light emitting diode having a single emitting part with a normal structure in accordance with an embodiment of the present disclosure. For instance, FIG. 3 shows an example (OLED D1) of the OLED D in FIGS. 1 and 2.

As illustrated in FIG. 3, the organic light emitting diode (OLED) D1 in accordance with an embodiment includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region and/or the green pixel region.

In an embodiment, the emissive layer 230 includes an emitting material layer (EML) 330 disposed between the first and second electrodes 210 and 220. The emissive layer 230 can include at least one of a hole transport layer (HTL) 320 disposed between the first electrode 210 and the EML 330 and an electron transport layer (ETL) 370 disposed between the second electrode 220 and the EML 330. In certain embodiments, the emissive layer 230 can further include at least one of a hole injection layer (HIL) 310 disposed between the first electrode 210 and the HTL 320 and an electron injection layer (EIL) 380 disposed between the second electrode 220 and the ETL 370. Alternatively, or additionally, the emissive layer 230 can further include a first exciton blocking layer, i.e. an electron blocking layer (EBL) disposed between the HTL 320 and the EML 330 and/or a second exciton blocking layer, i.e. a hole blocking layer (HBL) disposed between the EML 330 and the ETL 370.

The first electrode 210 can be an anode that provides holes into the EML 340. The first electrode 210 can include a conductive material having a relatively high work function value, for example, a transparent conductive oxide (TCO). In an embodiment, the first electrode 210 can include, but is not limited to, ITO, IZO, ITZO, SnO, ZnO, ICO, AZO, and/or combinations thereof.

The second electrode 220 can be a cathode that provides electrons into the EML 330. The second electrode 220 can include a conductive material having a relatively low work function value. For example, the second electrode 220 can include highly reflective material such as Al, Mg, Ca, Ag, alloy thereof and/or combinations thereof such as aluminum-magnesium alloy (Al—Mg).

The EML 330 includes a red emitting material layer (R-EML) 340, a green emitting material layer (G-EML) 350 disposed between the R-EML 340 and the second electrode 220 and an exciton control layer (ECL) 360 disposed between the R-EML 340 and the G-EML 350.

The R-EML 340 can include a first red host 342 and/or a second red host 344, and a red emitter (red dopant) 346. For example, the first red host 342 can be a P-type red host and the second red host 344 can be an N-type red host. The G-EML 350 can include a first green host 352 and/or a second green host 354, and a green emitter (green dopant) 356. For example, the first green host 352 can be a P-type green host and the second green host 354 can be an N-type green host. Substantial emission is occurred at each of the red emitter 346 and the green emitter 356 in the R-EML 340 and the G-EML 350, respectively. The ECL 360 can include at least one of a first compound 362 and a second compound 364.

Each of the first red host 342 as the P-type red host and the first green host 352 as the P-type green host has relatively beneficial hole affinity property compared to each of the second red host 344 as the N-type red host and the second green host 354 as the N-type green host, respectively. On the other hand, each of the second red host 344 and the second green host 354 has relatively beneficial electron affinity property compared to each of the first red host 342 and the first green host 352, respectively.

Each of the first red host 342 and the first green host 352 can independently include, but is not limited to, at least one a carbazole-containing organic compound, an aromatic and/or hetero aromatic amino-containing organic compound and a spirofluorene-containing organic compound. Each of the second red host 344 and the second green host 354 can independently include, but is not limited to, at least one of an azine-containing organic compound, a benzimidazole-containing organic compound and a quinazoline-containing organic compound.

For example, the first red host 342 as the P-type red host and the second red host 344 as the N-type red host can include, but is not limited to, 4,4′-bis(N-carbazolyl)-1,1′-biphenyl (CBP), 3,3′-Di(9H-carbazol-9-yl)-1,1′-biphenyl (mCBP), 2,2′-Di(9H-carbazol-9-yl)-1,1′-biphenyl (oCBP), 1,3-Di(9H-carbazol-9-yl)benzene (mCP), 9-(3-(9H-Carbazol-9-yl)phenyl)-9H-carbazole-3-carbonitrile (mCP-CN), Bis[2-(diphenylphosphino)phenyl]ether oxide (DPEPO), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 1,3,5-Tris(carbazol-9-yl)benzene (TCP), 4,4′-Bis(carbazole-9-yl)-2,2′-dimethylbiphenyl (CDBP), 2,7-Bis(carbazole-9-yl)-9,9-dimethylfluorene (DMFL-CBP), 2,2′,7,7′-Tetrakis(carbazol-9-yl)-9,9-spirofluorene (Spiro-CBP), 3,6-Bis(carbazole-9-yl)-9-(2-ethyl-hexyl)-9H-carbazole (TCz1), N4,N4,N4′,N4′-Tetra[(1,1′-biphenyl)-4-yl]-(1,1′-biphenyl)-4,4′-diamine (BPBPA), 1,3,5-Tris(N-phenylbenzimidazol-2-yl)benzene (TPBi), Tris(4-carbazoyl-9-yl-phenyl)amine(TCTA), the following red host and/or combinations thereof.

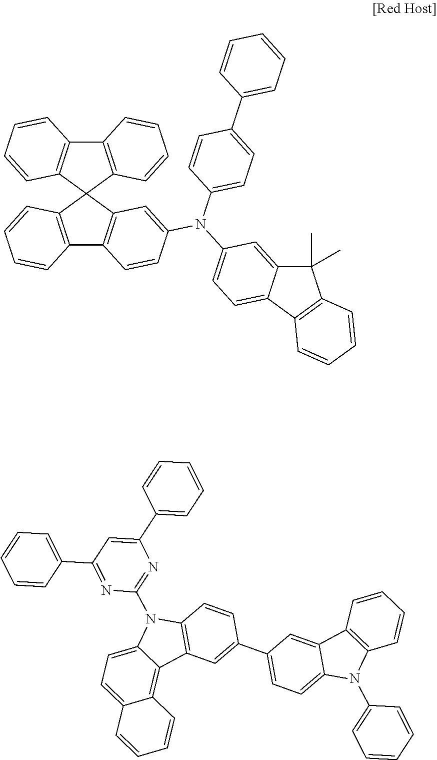 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2cc(-c3ccccc3)nc(-n3c4ccc(-c5ccc6c(c5)c5ccccc5n6-c5ccccc5)cc4c4c5ccccc5ccc43)n2)cc1]

The red emitter 346 can include at least one of a red phosphorescent material, a red fluorescent material and a red delayed fluorescent material. For example, the red emitter 346 can include, but is not limited to, Bis[2-(4,6-dimethyl)phenylquinoline](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Ir(Mphq)₃), Bis(2-phenylquinoline)(2,2,6,6-tetramethylheptene-3,5-dionate)iridium(III) (Ir(dpm)PQ₂), Tris(1-phenylisoquinoline)iridium(III) (Ir(piq)₃), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-Bis[2-(2-methylphenyl)-7-methyl-quinolato)iridium (Ir(dmpq)₃), quinoline](acetylacetonate)iridium(III) (Ir(dmpq)₂(acac)), Bis[2-(3,5-dimethylphenyl)-4-methyl-quinoline](acetylacetonate)iridium(III) (Ir(mphmq)₂(acac)), Tris(dibenzoylmethane)mono(1,10-phenanthroline)europium(III) (Eu(dbm)₃(phen)) and/or combinations thereof.

The contents of the red hosts 342 and 344 in the R-EML 340 can be between about 50 wt. % to about 99 wt. %, for example, about 80 wt. % to about 98 wt. %, and the contents of the red emitter 346 in the R-EML 340 can be between about 1 wt. % to about 50 wt. %, for example, about 2 wt. % to about 20 wt. %, but is not limited thereto. When the R-EML 340 includes the first red host 342 and the second red host 344, the first red host 342 and the second red host 344 can be mixed with, but is not limited to, a weight ratio of about 4:1 to about 1:4, for example, about 3:1 to about 1:3 or about 3:7 to about 7:3. For example, the R-EML 340 can have a thickness, but is not limited to, about 100 Å to about 500 Å, for example, about 200 Å to about 400 Å or about 250 Å to about 350 Å.

In another embodiment, the first green host 352 as the P-type green host and the second green host 354 as the N-type green host can include, but is not limited to, mCP-CN, CBP, mCBP, mCP, DPEPO, PPT, TmPyPB, PYD-2Cz, DCzDBT, DCzTPApCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, BCzPh, TCP, TCTA, CDBP, DMFL-CBP, Spiro-CBP, TCz1, the following green host and/or combinations thereof.

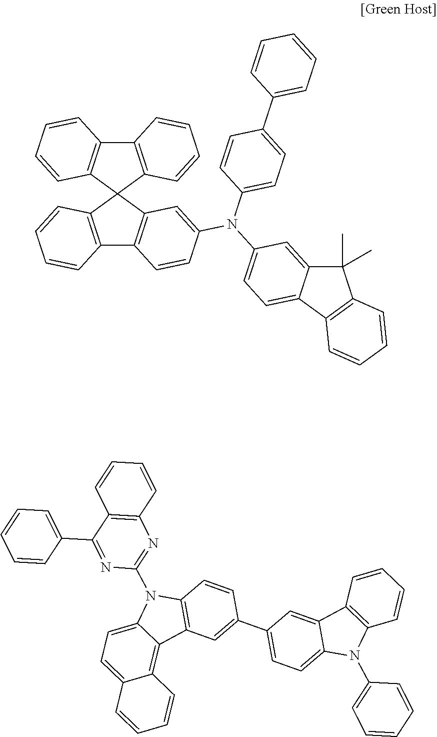 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2nc(-n3c4ccc(-c5ccc6c(c5)c5ccccc5n6-c5ccccc5)cc4c4c5ccccc5ccc43)nc3ccccc23)cc1]

The green emitter 356 can include at least one of a green phosphorescent material, a green fluorescent material and a green delayed fluorescent material. For example, the green emitter 356 can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the green hosts 352 and 354 in the G-EML 350 can be between about 50 wt. % to about 99 wt. %, for example, about 80 wt. % to about 95 wt. %, and the contents of the green emitter 356 in the G-EML 350 can be between about 1 wt. % to about 50 wt. %, for example, about 5 wt. % to about 20 wt. %, but is not limited thereto. When the G-EML 350 includes the first green host 352 and the second green host 354, the first green host 352 and the second green host 354 can be mixed with, but is not limited to, a weight ratio of about 4:1 to about 1:4, for example, about 3:1 to about 1:3 or about 3:7 to about 7:3. For example, the G-EML 350 can have a thickness, but is not limited to, about 100 Å to about 300 Å, for example, about 150 Å to about 250 Å.

In another embodiment, a yellow-green emitting material layer (YG-EML) can be disposed between the R-EML 340 and the ECL 360 or between the ECL 360 and the G-EML 350. The YG-EML can include a first yellow-green host and/or a second yellow-green host, and a yellow-green emitter (yellow-green dopant). For example, the first yellow-green host can be a P-type yellow-green host and the second yellow-green host can be an N-type yellow-green host. For example, the first yellow-green host can be identical to the first red host 342 and/or the first green host 352, and/or the second yellow-green host can be identical to the second red host 344 and/or the second green host 354.

The yellow-green emitter can include at least one of a yellow-green phosphorescent material, a yellow-green florescent material and a yellow-green delayed fluorescent material. For example, the yellow-green emitter can include, but is not limited to, 5,6,11,12-Tetraphenylnaphthalene (Rubrene), 2,8-Di-tert-butyl-5,11-bis(4-tert-butylphenyl)-6,12-diphenyltetrazene (TBRb), Bis(2-phenylbenzothiazolato)(acetylacetonate)iridium(III) (Ir(BT)₂(acac)), Bis(2-(9,9-diethyl-fluoren-2-yl)-1-phenyl-1H-benzo[d]imidazolate)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01), the following yellow-green emitter and/or combinations thereof.

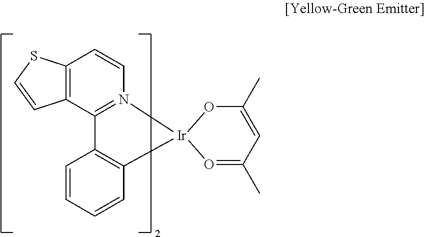

The contents of the yellow-green host in the YG-EML can be between about 50 wt. % to about 99 wt. %, for example, about 80 wt. % to about 95 wt. %, and the contents of the yellow-green emitter in the YG-EML can be between about 1 wt. % to about 50 wt. %, for example, about 5 wt. % to about 20 wt. %, but is not limited thereto. When the YG-EML includes the first yellow-green host and the second yellow-green host, the first yellow-green host and the second yellow-green host can be mixed with, but is not limited to, a weight ratio of about 4:1 to about 1:4, for example, about 3:1 to about 1:3 or about 3:7 to about 7:3.

As an example, the first compound 362 can be a P-type compound and the second compound 364 can be an N-type compound in the ECL 360. In other words, the first compound 362 can have beneficial hole affinity properties compared to the second compound 364 and the second compound 364 can have beneficial electron affinity properties compared to the first compound 362.

In one embodiment, the first compound 362 can be an aromatic and/or hetero aromatic amino-containing compound. For example, an aromatic group and/or a hetero aromatic group linked to the nitrogen atom of the amino group can have, but is not limited to, a spiro structure. As an example, the first compound 362 can include a compound having the following structure of Chemical Formula 1:

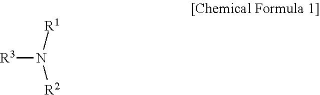

wherein, in Chemical Formula 1,
each of R¹, R² and R³ is independently an unsubstituted or substituted C₆-C₃₀ aryl group or an unsubstituted or substituted C₃-C₃₀ hetero aryl group.

As used herein, the term “unsubstituted” means that hydrogen is directly linked to a carbon atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group, and a group formed by any combination of these groups.

As used herein, the term “hetero” in terms such as “a hetero aryl group”, and “a hetero arylene group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

The aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aryl group or the hetero aryl group can consist of one to four aromatic and/or hetero aromatic rings. When the number of the aromatic and/or hetero aromatic rings becomes more than four, conjugated structure within the whole molecule becomes too long, thus, the organic compound can have too narrow of an difference. For example, each of the aryl group or the hetero aryl group can include independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

For example, at least one of R¹ to R³ in Chemical Formula 1 can be an aryl group and/or a hetero aryl group having a spiro moiety. The spiro moiety can include, but is not limited to, a bis-spirofluorene moiety and a spiro-fluorene-acridine moiety (e.g., spiro-fluorene-indolo-acridine moiety). In another embodiment, at least one of R¹ to R³ in Chemical Formula 1 can have, but is not limited to, a fluorene moiety (e.g., unsubstituted or at least one C₁-C₁₀ alkyl-substituted fluorenyl and spiro-fluorene moiety).

As an example, at least one of R¹ to R³ in Chemical Formula 1 can have the spiro moiety. In another embodiment, the aryl group and/or the hetero aryl group other than the spiro moiety among R¹ to R³ in Chemical Formula 1 can include, but is not limited to, an aryl group such as phenyl, biphenyl, naphthyl and a fluorenyl each of which can be unsubstituted or further substituted with a C₆-C₂₀ aryl group such as phenyl and/or a C₁-C₁₀ alkyl group such as methyl, or a hetero aryl group such as carbazolyl, dibenzofuranyl and dibenzothiophenyl each of which can be unsubstituted or further substituted with a C₆-C₂₀ aryl group such as phenyl and/or a C₁-C₁₀ alkyl group such as methyl. In another embodiment, at least one of R¹ to R³ in Chemical Formula 1 can have the fluorenyl moiety.

For example, the first compound 362 can include, but is not limited to, the following compounds of Chemical Formula 2:

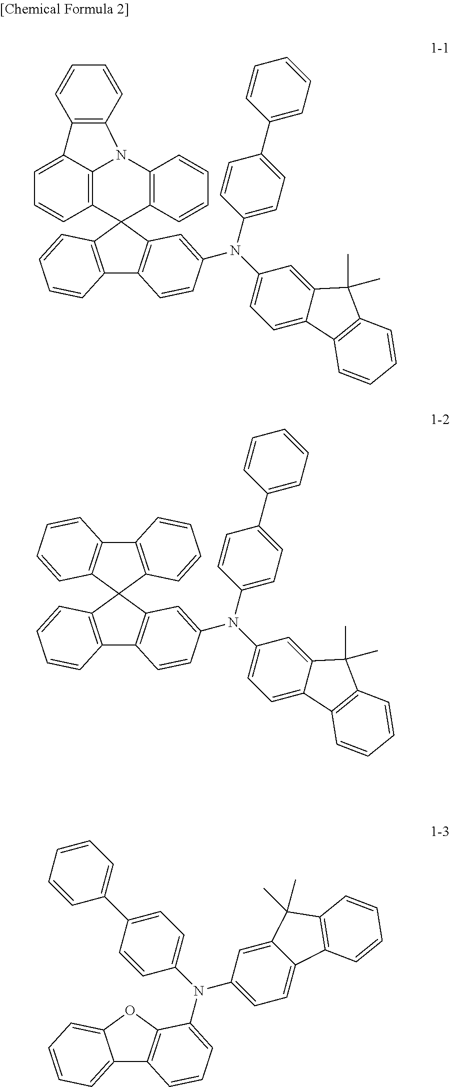 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3cccc4c3oc3ccccc34)cc21]

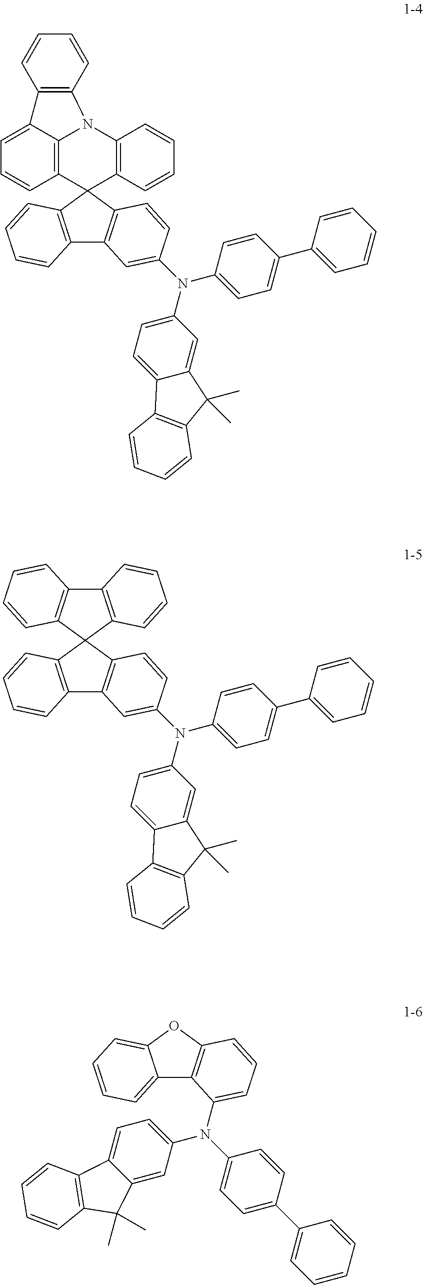 [SMILES: CC1(C)c2ccccc2-c2ccc(N(c3ccc(-c4ccccc4)cc3)c3ccc4c(c3)-c3ccccc3C43c4ccccc4-n4c5ccccc5c5cccc3c54)cc21 ; CC1(C)c2ccccc2-c2ccc(N(c3ccc(-c4ccccc4)cc3)c3ccc4c(c3)-c3ccccc3C43c4ccccc4-c4ccccc43)cc21 ; CC1(C)c2ccccc2-c2ccc(N(c3ccc(-c4ccccc4)cc3)c3cccc4oc5ccccc5c34)cc21]

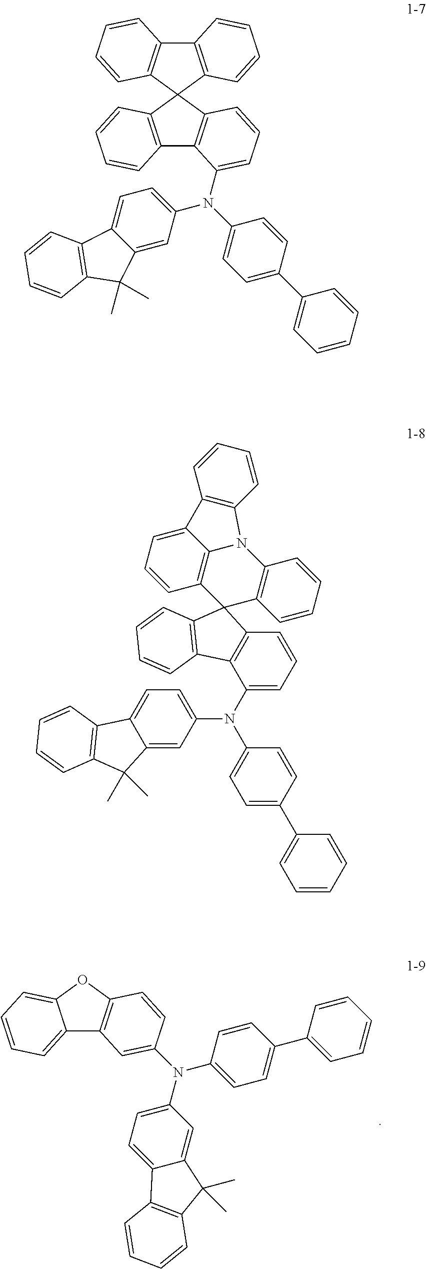 [SMILES: CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-n4c5ccccc5c5cccc3c54)cc21 ; CC1(C)c2ccccc2-c2ccc(N(c3ccc(-c4ccccc4)cc3)c3ccc4oc5ccccc5c4c3)cc21]

The second compound 364 can include at least one of an azine-containing compound and a quinazoline-containing compound. As an example, the second compound 364 can include a compound having the following structure of Chemical Formula 3:

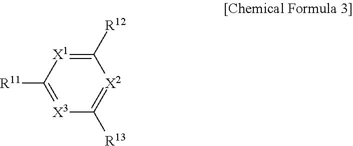

wherein, in Chemical Formula 3,
each of R¹¹, R¹² and R¹³ is independently hydrogen, an unsubstituted or substituted C₆-C₃₀ aryl group or an unsubstituted or substituted C₃-C₃₀ hetero aryl group, where at least one of R¹¹, R¹² and R¹³ has a moiety of the following structure of Chemical Formula 3A;
each of X¹, X² and X³ is independently CR¹⁴ or N, where at least two of X¹, X² and X³ is N;
R¹⁴ is hydrogen, and unsubstituted or substituted C₆-C₃₀ aryl group or an unsubstituted or substituted C₃-C₃₀ hetero aryl group, or
optionally,
adjacent R¹¹ and R¹⁴, adjacent R¹² and R¹⁴ and/or adjacent R¹³ and R¹⁴ are further linked together to form an unsubstituted or substituted C₆-C₂₀ aromatic ring,

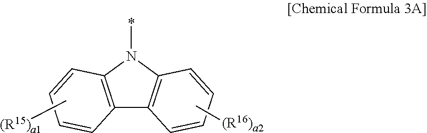

wherein, in Chemical Formula 3A,
each of R¹⁵ and R¹⁶ is independently an unsubstituted or substituted C₆-C₃₀ aryl group or an unsubstituted or substituted C₃-C₃₀ hetero aryl group, where each R¹⁵ is identical to or different from each other when a1 is 2, 3 or 4, and each R¹⁶ is identical to or different from each other when a2 is 2, 3 or 4, or
optionally,
two adjacent R¹⁵ when a1 is 2, 3 or 4, and/or
two adjacent R¹⁶ when a2 is 2, 3 or 4
are further linked together to form an unsubstituted or substituted C₆-C₂₀ aromatic ring;
each of a1 and a2 is independently 0, 1, 2, 3 or 4, where at least one of a1 and a2 is not 0; and
the asterisk indicates a link to a ring of Chemical Formula 3.

For example, a substituent other than the moiety among R¹¹ to R¹³ in Chemical Formula 3 can be unsubstituted or substituted phenyl, R¹⁴ and at least one of R¹¹ to R¹³ in Chemical Formula 3 can be further linked together to from an unsubstituted or substituted benzene ring, and/or R¹⁶ in Chemical Formula 3A can be unsubstituted or substituted carbazolyl. In another embodiment, two adjacent R¹⁵ in Chemical Formula 3A can be further linked together to from an unsubstituted or substituted (e.g., phenyl-substituted) benzene ring and/or two adjacent R¹⁶ in Chemical Formula 3A can be further linked together to from an unsubstituted or substituted (e.g., phenyl-substituted) indole ring, but is not limited thereto. As an example, the second compound 364 can include, but is not limited to, at least one of the following compounds of Chemical Formula 4:

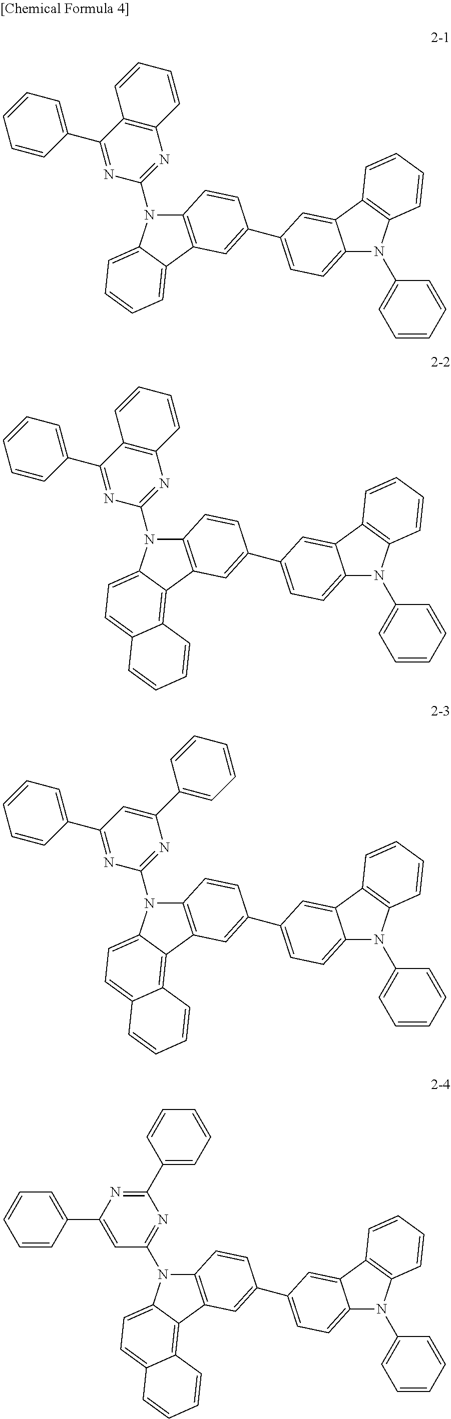 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2cc(-c3ccccc3)nc(-n3c4ccc(-c5ccc6c(c5)c5ccccc5n6-c5ccccc5)cc4c4c5ccccc5ccc43)n2)cc1 ; c1ccc(-c2cc(-n3c4ccc(-c5ccc6c(c5)c5ccccc5n6-c5ccccc5)cc4c4c5ccccc5ccc43)nc(-c3ccccc3)n2)cc1]

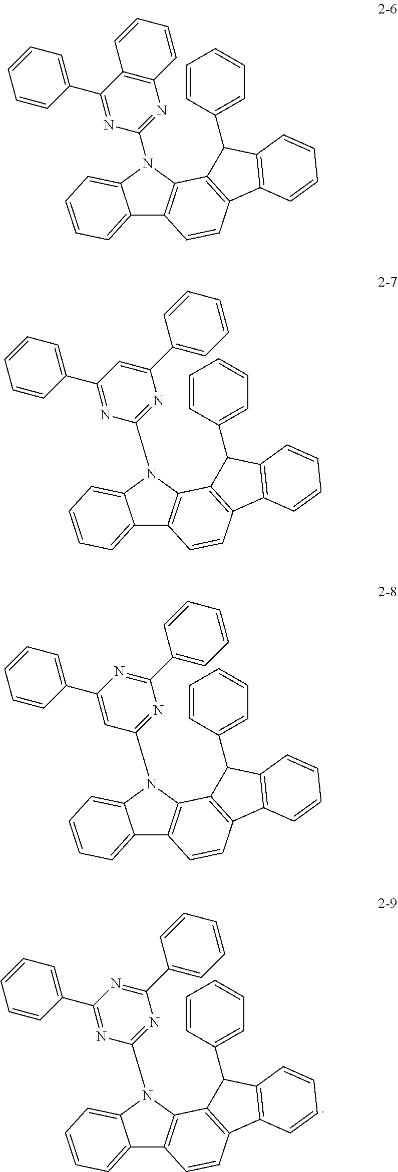 [SMILES: c1ccc(-c2nc(-n3c4ccccc4c4ccc5c(c43)C(c3ccccc3)c3ccccc3-5)nc3ccccc23)cc1 ; c1ccc(-c2cc(-c3ccccc3)nc(-n3c4ccccc4c4ccc5c(c43)C(c3ccccc3)c3ccccc3-5)n2)cc1 ; c1ccc(-c2cc(-n3c4ccccc4c4ccc5c(c43)C(c3ccccc3)c3ccccc3-5)nc(-c3ccccc3)n2)cc1 ; c1ccc(-c2nc(-c3ccccc3)nc(-n3c4ccccc4c4ccc5c(c43)C(c3ccccc3)c3ccccc3-5)n2)cc1]

In one embodiment, when the ECL 360 includes both the first compound 362 and the second compound 364, the first compound 362 and the second compound 364 in the ECL 360 can be mixed with, but is not limited to, a weight ratio of about 7:3 to about 3:7, for example, about 6:4 to about 4:6. In another embodiment, the ECL 360 can have a thickness, but is not limited to, about 10 Å to about 200 Å, for example, about 30 Å to about 150 Å or about 50 Å to about 100 Å.

The HIL 310 is disposed between the first electrode 210 and the HTL 320 and can improve an interface property between the inorganic first electrode 210 and the organic HTL 320. In one embodiment, hole injecting material in the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-Tetrafluoro-7,7,8,8-tetracyano-quinodimethane (F4-TCNQ), 1,3,4,5,7,8-hexafluoro-tetracyano-naphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), Di-[4-(N,N-di-p-tolyl-amino)-phenyl]cyclohexane (TAPC), the following hole injecting material and/or combinations thereof.

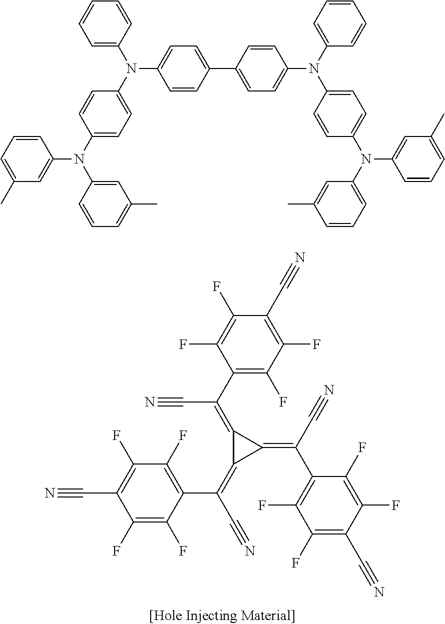 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

In another embodiment, the HIL 310 can include the hole transporting material described below doped with the hole injecting material. The doping hole injecting material can include, but is not limited to, HAT-CN, F4-TCNQ, F6-TCNNQ, the hole injecting material with a radialene structure and/or combinations thereof. In this case, the contents of the hole injecting material in the HIL 310 can be, but is not limited to, about 1 wt. % to about 10 wt. %. In certain embodiments, the HIL 310 can be omitted in compliance of the OLED D1 property.

The HTL 320 is disposed between the first electrode 210 and the EML 330. In one embodiment, the hole transporting material in the HTL 320 can include, but is not limited to, N,N′-Diphenyl-N,N′-bis(3-methylphenyl)-1,1′-biphenyl-4,4′-diamine (TPD), NPB(NPD), CBP, Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), TAPC, 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine, the following hole transporting material and/or combinations thereof.

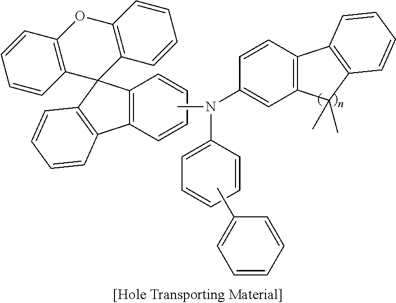

where, n is 1 or 2.

The ETL 370 and the EIL 380 can be laminated sequentially between the EML 330 and the second electrode 220. An electron transporting material included in the ETL 370 has high electron mobility so as to provide electrons stably with the EML 330 by fast electron transportation.

In one embodiment, electron transporting material in the ETL 370 can include at least one of an oxadiazole-containing compound, a triazole-containing compound, a phenanthroline-containing compound, a benzoxazole-containing compound, a benzothiazole-containing compound, a benzimidazole-containing compound, a triazine-containing compound and/or combinations thereof.

For example, the electron transporting material in the ETL 370 can include, but is not limited to, tris-(8-hydroxyquinoline) aluminum (Alq₃), 2-biphenyl-4-yl-5-(4-t-butylphenyl)-1,3,4-oxadiazole (PBD), spiro-PBD, lithium quinolate (Liq), 2,2′,2″-(1,3,5-benzenetriyl)-tris(1-phenyl-1-H-benzimidazole) (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[(9,9-bis(3′-((N,N-dimethyl)-N-ethylammonium)-propyl)-2,7-fluorene)-alt-2,7-(9,9-dioctylfluorene)] dibromide (PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN), the following electron transporting material and/or combinations thereof.

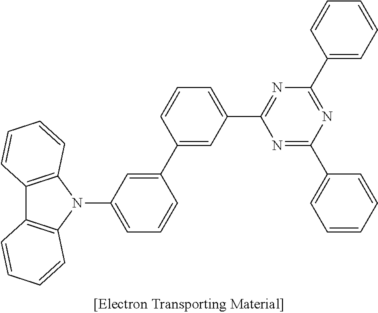 [SMILES: c1ccc(-c2nc(-c3ccccc3)nc(-c3cccc(-c4cccc(-n5c6ccccc6c6ccccc65)c4)c3)n2)cc1]

The EIL 380 is disposed between the second electrode 220 and the ETL 370, and can improve physical properties of the second electrode 220 and therefore, can enhance the lifespan of the OLED D1. In one embodiment, electron injecting material in the EIL 380 can include, but is not limited to, an alkali metal halide and/or an alkaline earth metal halide such as LiF, CsF, NaF, BaF₂ and the like, and/or an organometallic compound such as Liq, lithium benzoate, sodium stearate, and the like.

In another embodiment, the EIL 380 can include the above electron transporting material doped with an alkali metal such as Li, Na and the like and/or an alkaline earth metal such as Mg and the like. In this case, the content of the alkali metal and/or the alkaline earth metal can be, but is not limited to, about 0.5 wt. % to about 20 wt. %.

In another embodiment, the ETL 370 and the EIL 380 can have a single layered structure. In this case, the above electron transporting material and/or the electron injecting material can be mixed with each other. As an example, the ETL/EIL can include two or more different electron transporting materials. For example, two electron transporting materials in the ETL/EIL are mixed with, but are not limited to, a weight ratio of about 3:7 to about 7:3.

When holes are transferred to the second electrode 220 via the EML 330, the OLED D1 can have short lifespan and reduced luminous efficiency. In order to prevent those phenomena, the OLED D1 in accordance with one embodiment can further include at least one exciton blocking layer disposed adjacently to the EML 330. For example, the OLED D1 in accordance with one embodiment can further include an electron blocking layer (EBL) between the HTL 320 and the EML 330 so as to control and prevent electron transportation and/or a hole blocking layer (HBL) between the EML 330 and the ETL 370 so that holes cannot be transferred from the EML 330 to the ETL 370.

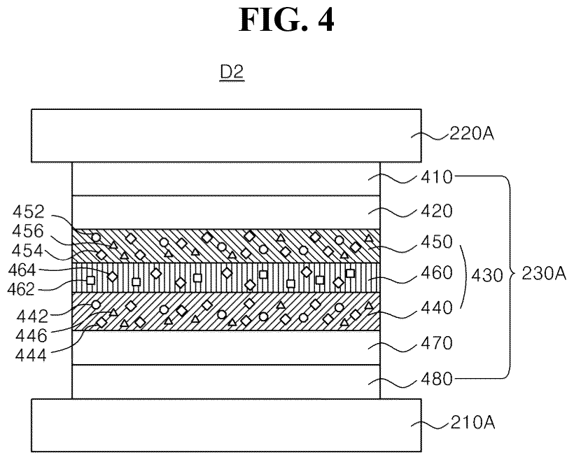

FIG. 4 illustrates a cross-sectional view of an organic light emitting diode having an inverted structure in accordance with another embodiment of the present disclosure. As illustrated in FIG. 4, an organic light emitting diode D2 in accordance with another embodiment includes a first electrode 210A, a second electrode 220A facing the first electrode 210A and an emissive layer 230A disposed between the first and second electrodes 210A and 220A.

The emissive layer 230A includes an emitting material layer (EML) 430. The emissive layer 230A can further include at least one of an electron transport layer (ETL) 470 disposed between the first electrode 210A and the EML 430 and a hole transport layer (HTL) 420 disposed between the second electrode 220A and the EML 430. In certain embodiments, the emissive layer 230A can further include at least one of an electron injection layer (EIL) 480 disposed between the first electrode 210A and the ETL 470 and a hole injection layer (HIL) 410 disposed between the second electrode 220A and the HTL 420. Alternatively, or additionally, the emissive layer 230A can further include a hole blocking layer (HBL) disposed between the ETL 470 and the EML 430 and/or an electron blocking layer (EBL) disposed between the EML 430 and the HTL 420.

The first electrode 210A can be a cathode that provides electrons to the EML 430. The first electrode 210A can include TCO with relatively large work function value. For example, the first electrode 210A can include, but is not limited to, ITO, IZO, ITZO, SnO, ZnO, ICO and/or AZO.

The second electrode 220A can be an anode that provides holes to the EML 430. The second electrode 220A can include conductive material with relatively low work function value, for example, highly reflective material such as Al, Mg, Ca, Ag, alloy thereof and/or combinations thereof.

The EML 430 includes a red emitting material layer (R-EML) 440 disposed between the ETL 470 and the HTL 420, a green emitting material layer (G-EML) 450 disposed between the R-EML 440 and the HTL 420 and an exciton control layer (ECL) 460 disposed between the R-EML 440 and the G-EML 450. Alternatively, or additionally, a yellow-green emitting material layer (YG-EML) can be disposed between the R-EML 440 and the ECL 460 or the G-EML 450 and the ECL 460.

The R-EML 440 can include a first red host 442 and/or a second red host 444, and a red emitter 446. For example, the first red host 442 can be a P-type red host and the second red host 444 can be an N-type red host. The G-EML 450 can include a first green host 452 and/or a second green host 454, and a green emitter 456. For example, the first green host 452 can be a P-type green host and the second green host 454 can be an N-type green host. The ECL 460 can include at least one of a first compound 462 and a second compound 464.

The materials and contents thereof in the emissive layer 230A can be identical to corresponding materials and contents thereof with referring to FIG. 3 except of the function of the first and second electrodes 210A and 220A and the relative locations of the HIL 410, the HTL 420, the ETL 470 and the EIL 480.

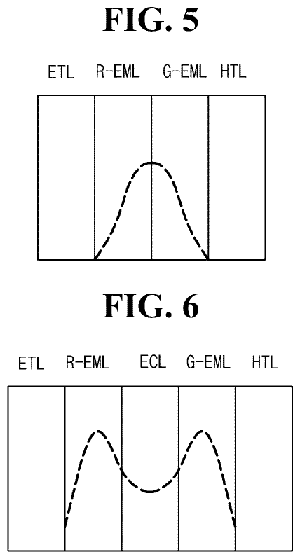

FIG. 5 illustrates a schematic diagram showing exciton recombination zone in a red emitting material layer and a green emitting material layer in a conventional organic light emitting diode. As illustrated in FIG. 5, a red emitting material layer R-EML is disposed adjacently to an electron transport layer ETL and a green emitting material layer G-EML is disposed adjacently to a hole transport layer HTL in a conventional organic light emitting diode with an inverted structure. As the material used in the cathode in the inverted structure has relatively highest occupied molecular orbital (HOMO) energy level compared to the normal structure, charge injection barrier, particularly, hole injection barrier is very high.

In addition, hole mobility of the P-type host in the G-EML is not high. The green host's ratio is optimized for charge balance under the condition of high P-type host. In the G-EML disposed adjacently to the HTL, the host ratio is optimized under conditions in which holes of main carriers are high. Accordingly, excitons are mainly concentrated at an interface between the R-EML and the G-EML in the conventional organic light emitting diode.

As exciton recombination is generated mainly at the interface between the R-EML and the G-EML, local load is occurred at the interface area between the R-EML and the G-EML. In this case, as the luminous materials in the R-EML and the G-EML degrade, the luminous efficiency of the conventional organic light emitting diode can be reduced.

FIG. 6 illustrates a schematic diagram showing exciton recombination zone in a red emitting material layer and a green emitting material layer in accordance with one embodiment of the present disclosure. As illustrated in FIG. 6, when the ECL 360 or 460 is disposed between the R-EML 340 or 440 and the G-EML 350 or 450, the exciton recombination zone is distributed uniformly within the entire area of the R-EML 340 or 440 to the G-EML 350 or 450. The degradations of the luminous materials caused by the concentrated recombination zone are minimized so that the luminous lifespan of the OLED D1 or D2 can be maximized.

In one embodiment, each of the R-EML 340 or 440 and the G-EML 350 or 450 can independently include phosphorescent emitters 346, 356, 446 and/or 456, respectively. In this case, exciton energy can be transferred to the phosphorescent emitters 346, 356, 446 and/or 456 from the hosts 342, 344, 352, 354, 442, 444, 452 and/or 454 based upon the long lifespan of triplet excitons. As the wide exciton recombination zone is generated through the entire area of the EML 330 or 430, the luminous lifespan of the OLED D1 and/or D2 can be improved greatly.

Returning to FIGS. 3 and 4, in one embodiment, a difference between a HOMO energy level of the first compound 362 or 462 and a HOMO energy level of the second compound 364 or 464 can be equal to or less than about 0.2 eV. In another embodiment, the difference between the HOMO energy level of the first compound 362 or 462 and the HOMO energy level of the second compound 364 or 464 can be equal to or less than about 0.15 eV. In this case, the luminous efficiency and the luminous lifespan of the OLED D1 or D2 can be improved without generating exciplex between the first compound 362 or 462 and the second compound 364 or 464.

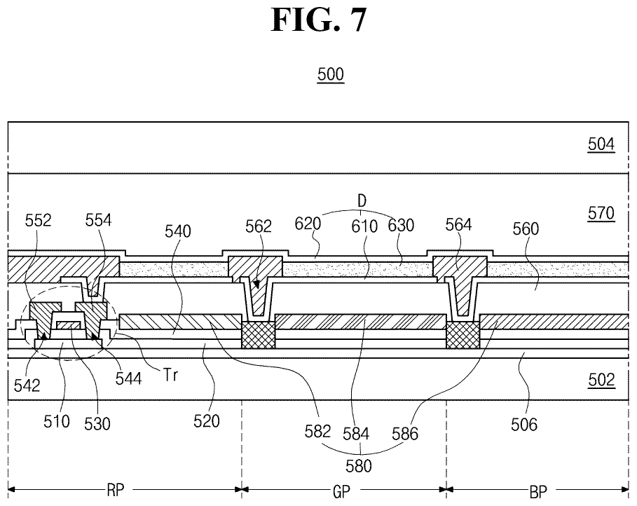

An organic light emitting display device and an organic light emitting diode with a single emitting unit emitting red color light and green color light are described in the above embodiment. In another embodiment, an organic light emitting display device can implement full-color including white color. As an example, FIG. 7 illustrates a schematic cross-sectional view of an organic light emitting display device in accordance with another embodiment of the present disclosure.

As illustrated in FIG. 7, an organic light emitting display device 500 includes a first substrate 502 that defines each of a red pixel region RP, a green pixel region GP and a blue pixel region BP, a second substrate 504 facing the first substrate 502, a thin film transistor Tr on the first substrate 502, an organic light emitting diode (OLED) D disposed between the first and second substrates 502 and 504 and emitting white (W) light, and a color filter layer 580 disposed between the OLED D and the first substrate 502. The organic light emitting display device 500 can include a plurality of such pixel regions arranged in a matrix configuration or other suitable configurations.

Each of the first and second substrates 502 and 504 can include, but is not limited to, glass, flexible material and/or polymer plastics. For example, each of the first and second substrates 502 and 504 can be made of PI, PES, PEN, PET, PC and/or combinations thereof. The first substrate 502, on which a thin film transistor Tr and the OLED D are arranged, forms an array substrate. In certain embodiments, the second substrate 504 can be omitted. As such, the organic light emitting display device 500 or any other display device of the present disclosure can be flexible, bendable, foldable, etc.

A buffer layer 506 can be disposed on the first substrate 502. The thin film transistor Tr is disposed on the buffer layer 506 correspondingly to each of the red pixel region RP, the green pixel region GP and the blue pixel region BP. In certain embodiments, the buffer layer 506 can be omitted.

A semiconductor layer 510 is disposed on the buffer layer 506. The semiconductor layer 510 can be made of or include oxide semiconductor material or polycrystalline silicon.

A gate insulating layer 520 including an insulating material, for example, inorganic insulating material such as silicon oxide (SiOₓ, wherein 0<x≤2) or silicon nitride (SiNₓ, wherein 0<x≤2) is disposed on the semiconductor layer 510.

A gate electrode 530 made of a conductive material such as a metal is disposed over the gate insulating layer 520 so as to correspond to a center or middle area of the semiconductor layer 510. An interlayer insulating layer 540 including an insulating material, for example, inorganic insulating material such as SiOₓ or SiNₓ, or an organic insulating material such as benzocyclobutene or photo-acryl, is disposed on the gate electrode 530.

The interlayer insulating layer 540 has first and second semiconductor layer contact holes 542 and 544 that expose or do not cover a portion of the surface nearer to the opposing ends than to a center of the semiconductor layer 510. The first and second semiconductor layer contact holes 542 and 544 are disposed on opposite sides of the gate electrode 530 with spacing apart from the gate electrode 530.

A source electrode 552 and a drain electrode 554, which are made of or include a conductive material such as a metal, are disposed on the interlayer insulating layer 540. The source electrode 552 and the drain electrode 554 are spaced apart from each other with respect to the gate electrode 530. The source electrode 552 and the drain electrode 554 contact both sides of the semiconductor layer 510 through the first and second semiconductor layer contact holes 542 and 544, respectively. The source and drain electrodes 552 and 554 can be switched with each other depending on the types of transistors and display structure used.

The semiconductor layer 510, the gate electrode 530, the source electrode 552 and the drain electrode 554 constitute the thin film transistor Tr, which acts as a driving element.

In some aspects, as shown in FIG. 1, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 530 for one frame.

A passivation layer 560 is disposed on the source electrode 552 and the drain electrode 554 and covers the thin film transistor Tr over the whole first substrate 502. The passivation layer 560 has a drain contact hole 562 that exposes or does not cover the drain electrode 554 of the thin film transistor Tr.

The OLED D is located on the passivation layer 560. The OLED D includes a first electrode 610 that is connected to the drain electrode 554 of the thin film transistor Tr, a second electrode 620 facing the first electrode 610 and an emissive layer 630 disposed between the first and second electrodes 610 and 620.

The first electrode 610 formed for each pixel region RP, GP or BP can be an anode or a cathode and can include a conductive material having relatively high work function value. For example, the first electrode 610 can include, but is not limited to, ITO, IZO, ITZO, SnO, ZnO, ICO, AZO, and/or combinations thereof.

A bank layer 564 is disposed on the passivation layer 560 in order to cover edges of the first electrode 610. The bank layer 564 exposes or does not cover a center of the first electrode 610 corresponding to each of the red pixel region RP, the green pixel region GP and the blue pixel region BP. In certain embodiments, the bank layer 564 can be omitted.

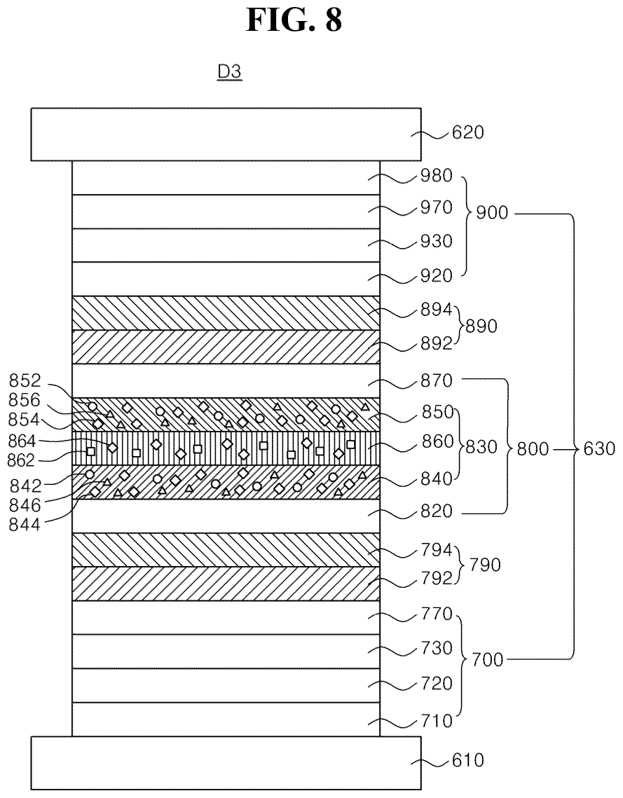

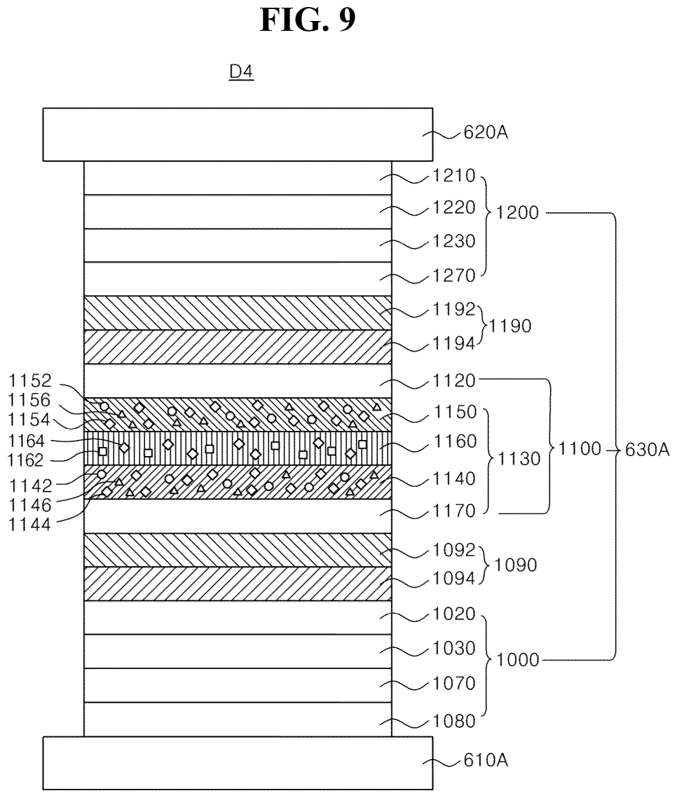

The emissive layer 630 that can include multiple emitting parts is disposed on the first electrode 610. As illustrated in FIGS. 8 and 9 as one example, the emissive layer 630 can include multiple emitting parts 700, 800, 900, 1000, 1100 and 1200 and at least one charge generation layer 790, 890, 1090 and 1190. Each of the emitting parts 700, 800, 900, 1000, 1100 and 1200 includes at least one emitting material layer and can further include a hole injection layer, a hole transport layer, an electron blocking layer, a hole blocking layer, an electron transport layer and/or an electron injection layer. FIG. 7 will be discussed in more detail later.

Referring back to FIG. 7, the second electrode 620 can be disposed on the first substrate 502 above which the emissive layer 630 can be disposed. The second electrode 620 can be disposed over a whole display area, can include a conductive material with a relatively low work function value compared to the first electrode 610, and can be a cathode providing electrons or an anode proving holes. For example, the second electrode 620 can include, but is not limited to, highly reflective material such as Al, Mg, Ca, Ag, alloy thereof, and/or combinations thereof such as Al—Mg.

The color filter layer 580 is disposed between the first substrate 502 and the OLED D, for example, the interlayer insulating layer 540 and the passivation layer 560. The color filter layer 580 can include a red color filter pattern 582, a green color filter pattern 584 and a blue color filter pattern 586 each of which is disposed correspondingly to the red pixel region RP, the green pixel region GP and the blue pixel region BP, respectively.

In addition, an encapsulation film (encapsulation layer/unit) 570 can be disposed on the second electrode 620 in order to prevent or reduce outer moisture from penetrating into the OLED D. The encapsulation film 570 can have, but is not limited to, a laminated structure including a first inorganic insulating film, an organic insulating film and a second inorganic insulating film (e.g., film 170 in FIG. 2). In addition, a polarizing plate can be attached onto the second substrate 504 to reduce reflection of external light. For example, the polarizing plate can be a circular polarizing plate.

In FIG. 7, the light emitted from the OLED D is transmitted through the first electrode 610 and the color filter layer 580 is disposed under the OLED D. The organic light emitting display device 500 can be a bottom-emission type. Alternatively, the light emitted from the OLED D is transmitted through the second electrode 620 and the color filter layer 580 can be disposed on the OLED D when the organic light emitting display device 500 is a top-emission type. In this case, the color filter layer 580 can be attached to the OLED D by adhesive layer. Alternatively, the color filter layer 580 can be disposed directly on the OLED D.

In addition, a color conversion layer can be formed or disposed between the OLED D and the color filter layer 580. The color conversion layer can include a red color conversion layer, a green color conversion layer and a blue color conversion layer each of which is disposed correspondingly to each pixel region (RP, GP and BP), respectively, so as to convert the white (W) color light to each of a red, green and blue color lights, respectively. For example, the color conversion layer can include quantum dots so that the color purity of the organic light emitting display device 500 can be further improved. Alternatively, the organic light emitting display device 500 can comprise the color conversion layer instead of the color filter layer 580.

As described above, the white (W) color light emitted from the OLED D is transmitted through the red color filter pattern 582, the green color filter pattern 584 and the blue color filter pattern 586 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will now be described in more detail. An example of the OLED D of FIG. 7 is shown in FIG. 8 as an OLED D3. Particularly, FIG. 8 illustrates a schematic cross-sectional view of an organic light emitting diode of a normal structure having a tandem structure of three emitting parts.

As illustrated in FIG. 8, the OLED D3 in accordance with another embodiment includes first and second electrodes 610 and 620 facing each other and an emissive layer 630 disposed between the first and second electrodes 610 and 620. The emissive layer 630 includes a first emitting part 700 disposed between the first and second electrodes 610 and 620, a second emitting part 800 disposed between the first emitting part 700 and the second electrode 620, a third emitting part 900 disposed between the second emitting part 800 and the second electrode 620, a first charge generation layer (CGL1) 790 disposed between the first and second emitting parts 700 and 800, and a second charge generation layer (CGL2) 890 disposed between the second and third emitting parts 800 and 900.

The first electrode 610 can be an anode and can include a conductive material having relatively high work function value such as TCO. In one embodiment, the first electrode 610 can include ITO, IZO, ITZO, SnO, ZnO, ICO and/or AZO. The second electrode 620 can be a cathode and can include a conductive material with a relatively low work function value, for example, highly reflective material such as Al, Mg, Ca, Ag, alloy thereof and/or combination thereof.

The first emitting part 700 includes a first emitting material layer (EML1) 730. The first emitting part 700 can include at least one of a hole injection layer (HIL) 710 disposed between the first electrode 610 and the EML1 730, a first hole transport layer (HTL1) 720 disposed between the HIL 710 and the EML1 730, and a first electron transport layer (ETL1) 770 disposed between the EML1 730 and the CGL1 790. Alternatively, or additionally, the first emitting part 700 can further include a first electron blocking layer (EBL1) disposed between the HTL1 720 and the EML1 730 and/or a first hole blocking layer (HBL1) disposed between the EML1 730 and the ETL1 770.

The second emitting part 800 includes a second emitting material layer (EML2) 830. The second emitting part 800 can include at least one of a second hole transport layer (HTL2) 820 disposed between the CGL1 790 and the EML2 830 and a second electron transport layer (ETL2) 870 disposed between the EML2 830 and the CGL2 890. Alternatively, or additionally, the second emitting part 800 can further include at least one of a second electron blocking layer (EBL2) disposed between the HTL2 820 and the EML2 830 and a second hole blocking layer (HBL2) disposed between the EML2 830 and the ETL2 870.

The third emitting part 900 includes a third emitting material layer (EML3) 930. The third emitting part 900 can include at least one of a third hole transport layer (HTL3) 920 disposed between the CGL2 890 and the EML3 930, a third electron transport layer (ETL3) 970 disposed between the EML3 930 and the second electrode 620, and an electron injection layer (EIL) 980 disposed between the ETL3 970 and the second electrode 620. Alternatively, or additionally, the third emitting part 900 can further include at least one of a third electron blocking layer (EBL3) disposed between the HTL3 920 and the EML3 930 and a third hole blocking layer (HBL3) disposed between the EML3 930 and the ETL3 970.

In one embodiment, one or two of the EML1 730, the EML2 830 and the EML3 930 emit blue color light and another of the EML1 730, the EML2 830 and the EML3 930 emits red to green color light, so that the OLED D3 can implement white (W) color emission. Hereinafter, the OLED D3 where the EML1 730 and the EML3 930 emits blue color light and the EML2 830 emits red to green color lights will be described in more detail.

The HIL 710 is disposed between the first electrode 610 and the HTL1 720 and improves an interface property between the inorganic first electrode 610 and the organic HTL1 720. In one embodiment, hole injecting material in the HIL 710 can include, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, TAPC, the above hole injecting material and/or combinations thereof.

In another embodiment, the HIL 710 can include the hole transporting material doped with the hole injecting material. In certain embodiments, the HIL 710 can be omitted in compliance of the OLED D3 property.

Each of the HTL1 720, the HTL2 820 and the HTL3 920 can facilitate the hole transportation in the first emitting part 700, the second emitting part 800 and the third emitting part 900, respectively. In one embodiment, hole transporting material in each of the HTL1 720, the HTL2 820 and the HTL3 920 can independently include, but is not limited to, TPD, NPB (NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine, the above hole transporting material and/or combination thereof.

Each of the ETL1 770, the ETL2 870 and the ETL3 970 can facilitate electron transportation in the first emitting part 700, the second emitting part 800 and the third emitting part 900, respectively. As an example, electron transporting material in each of the ETL1 770, the ETL2 870 and the ETL3 970 can independently include at least one of an oxadiazole-containing compound, a triazole-containing compound, a phenanthroline-containing compound, a benzoxazole-containing compound, a benzothiazole-containing compound, a benzimidazole-containing compound and a triazine-containing compound. For example, the electron transporting material in each of the ETL1 770, the ETL2 870 and the ETL3 970 can independently include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN, the above electron transporting material and/or combinations thereof.

The EIL 980 is disposed between the second electrode 620 and the ETL3 970, and can improve physical properties of the second electrode 620 and therefore, can enhance the lifespan of the OLED D3. In one embodiment, electron injecting material in the EIL 980 can include, but is not limited to, an alkali metal halide or an alkaline earth metal halide such as LiF, CsF, NaF, BaF₂ and the like, and/or an organometallic compound such as Liq, lithium benzoate, sodium stearate, and the like. In another embodiment, the EIL 980 can include the electron transporting material doped with the alkali metal and/or the alkaline earth metal.

The CGL1 790 is disposed between the first emitting part 700 and the second emitting part 800. The CGL1 790 includes a first N-type charge generation layer (N-CGL1) 792 disposed between the ETL1 770 and the HTL2 820, and a first P-type charge generation layer (P-CGL1) 794 disposed between the N-CGL1 792 and the HTL2 820.

The CGL2 890 is disposed between the second emitting part 800 and the third emitting part 900. The CGL2 890 includes a second N-type charge generation layer (N-CGL2) 892 disposed between the ETL2 870 and the HTL3 920, and a second P-type charge generation layer (P-CGL2) 894 disposed between the N-CGL2 892 and the HTL3 920.

Each of the N-CGL1 792 and the N-CGL2 892 provides electrons to the EML1 730 of the first emitting part 700 and the EML2 830 of the second emitting part 800, respectively. Each of the P-CGL1 794 and the P-CGL2 894 provides holes to the EML2 830 of the second emitting part 800 and the EML3 930 of the third emitting part 900, respectively.

Each of the N-CGL1 792 and the N-CGL2 892 can be an organic layer with electron transporting material doped with an alkali metal such as Li, Na, K and Cs and/or an alkaline earth metal such as Mg, Sr, Ba and Ra. For example, the contents of the alkali metal and/or the alkaline earth metal in each of the N-CGL1 792 and the N-CGL2 892 can be, but is not limited to, between about 0.1 wt. % and about 30 wt. %, for example, about 1 wt. % and about 10 wt. %.

In one embodiment, each of the P-CGL1 794 and the P-CGL2 894 can include, but is not limited to, inorganic material selected from the group consisting of WOₓ, MoOₓ, Be₂O₃, V₂O₅ and/or combinations thereof. In another embodiment, each of the P-CGL1 794 and the P-CGL2 894 can include organic material of the hole transporting material doped with the hole injecting material (e.g., organic material such as HAT-CN, F4-TCNQ, F6-TCNNQ and/or the hole injecting material with the radialene structure). In this case, the contents of the hole injecting material in the P-CGL1 794 and the P-CGL2 894 can be, but is not limited to, between about 0.5 wt. % and about 20 wt. %.

Each of the EML1 730 and the EML3 930 can be a blue emitting material layer (B-EML). In this case, each of the EML1 730 and the EML3 930 can be a blue emitting material layer, a sky blue emitting material layer and/or a deep blue emitting material layer. Each of the EML1 730 and the EML3 930 can include a blue host and a blue emitter (blue dopant). The blue host can include at least one of a P-type blue host and an N-type blue host.

For example, the blue host can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue emitter can include at least one of a blue phosphorescent material, a blue fluorescent material and a blue delayed fluorescent material. For example, the blue emitter can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl-9,9-spirofluorene (spiro-DPVBi), 1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tetr-butylperylene (TBPe), Bis((2-hydroxylphenyl)-pyridine)beryllium (Bepp₂), 9-(9-Phenylcarbazol-3-yl)-10-(naphthalen-1-yl)anthracene (PCAN), mer-Tris(1-phenyl-3-methylimidazolin-2-ylidene-C,C(2))′iridium(III) (mer-Ir(pmi)₃), fac-Tris(1,3-diphenyl-benzimidazolin-2-ylidene-C,C(2))′iridium(III) (fac-Ir(dpbic)₃), Bis(3,4,5-trifluoro-2-(2-pyridyl)phenyl-(2-carboxypyridyl))iridium(III) (Ir(tfpd)₂pic), tris(2-(4,6-difluorophenyl)pyridine)iridium(III) (Ir(Fppy)₃), Bis[2-(4,6-difluorophenyl)pyridinato-C²,N](picolinato)iridium(III) (FIrpic), DABNA-1, DABNA-2, t-DABNA, v-DABNA and/or combinations thereof.

The contents of blut host in each of the EML1 730 and the EML3 930 can be between about 50 wt. % to about 99 wt. %, for example, about 80 wt. % to about 95 wt. %, and the contents of the blue emitter in each of the EML1 730 and the EML3 930 can be between about 1 wt. % to about 50 wt. %, for example, about 5 wt. % to about 20 wt. %, but is not limited thereto. When each of the EML1 730 and the EML3 930 includes the P-type blue host and the N-type blue host, the P-type blue host and the N-type blue host can be mixed with, but is not limited to, a weight ratio of about 4:1 to about 1:4, for example, about 3:1 to about 1:3.

The EML2 830 includes a red emitting material layer (R-EML) 840 disposed between the HTL2 820 and the ETL2 870, a green emitting material layer (G-EML) 850 disposed between the R-EML 840 and the ETL2 870 and an exciton control layer (ECL) 860 disposed between the R-EML 840 and the G-EML 850. In another embodiment, the EML2 830 can further include a yellow-green emitting material layer (YG-EML) disposed between the R-EML 840 and the ECL 860 or between the ECL 860 and the G-EML 850.

The R-EML 840 includes a first red host 842 and/or a second red host 844, and a red emitter (red dopant) 846. The first red host 842 can be a P-type red host and/or the second red host 846 can be an N-type red host. The G-EML 850 includes a first green host 852 and/or a second green host 854, and a green emitter (green dopant) 856. The first green host 852 can be a P-type green host and/or the second green host 854 can be an N-type green host. The ECL 860 includes a first compound 862 and/or a second compound 864. The materials and the contents thereof in the EML2 830 can be identical to the corresponding materials and the contents thereof with referring to FIGS. 4 to 6.

FIG. 9 illustrates a cross-sectional view of an organic light emitting diode having an inverted structure and a tandem structure of multiple emitting parts in accordance with another embodiment of the present disclosure.

As illustrated in FIG. 9, an OLED D4 in accordance with another embodiment includes a first electrode 610A, a second electrode 620A facing the first electrode 610A and an emissive layer 630A disposed between the first and second electrodes 610A and 620A. The emissive layer 630A includes a first emitting part 1000 disposed between the first electrode 610A and the second electrode 620A, a second emitting part 1100 disposed between the first emitting part 1000 and the second electrode 620A, a third emitting part 1200 disposed between the second emitting part 1100 and the second electrode 620A, a first charge generation layer (CGL1) 1090 disposed between the first emitting part 1000 and the second emitting part 1100, and a second charge generation layer (CGL2) 1190 disposed between the second emitting part 1100 and the third emitting part 1200.

The first electrode 610A can be a cathode and can include a conductive material having relatively high work function value such as TCO. In one embodiment, the first electrode 610A can include ITO, IZO, ITZO, SnO, ZnO, ICO and/or AZO. The second electrode 620A can be an anode and can include a conductive material with a relatively low work function value, for example, highly reflective material such as Al, Mg, Ca, Ag, alloy thereof and/or combination thereof.

The first emitting part 1000 includes a first emitting material layer (EML1) 1030. The first emitting part 1000 can include at least one of an electron injection layer (EIL) 1080 disposed between the first electrode 610A and the EML1 1030, a first electron transport layer (ETL1) 1070 disposed between the EIL 1080 and the EML1 1030, and a first hole transport layer (HTL1) 1020 disposed between the EML1 1030 and the CGL1 1090. Alternatively, or additionally, the first emitting part 1000 can further include a first hole blocking layer (HBL1) disposed between the ETL1 1070 and the EML1 1030 and/or a first electron blocking layer (EBL1) disposed between the EML1 1030 and the HTL1 1020.

The second emitting part 1100 includes a second emitting material layer (EML2) 1130. The second emitting part 1100 can include at least one of a second electron transport layer (ETL2) 1170 disposed between the CGL1 1090 and the EML2 1130 and a second hole transport layer (HTL2) 1120 disposed between the EML2 1130 and the CGL2 1190. Alternatively, or additionally, the second emitting part 1100 can further include at least one of a second hole blocking layer (HBL2) disposed between the ETL2 1170 and the EML2 1130 and a second electron blocking layer (EBL2) disposed between the EML2 1130 and the HTL2 1120.

The third emitting part 1200 includes a third emitting material layer (EML3) 1230. The third emitting part 1200 can include at least one of a third electron transport layer (ETL3) 1270 disposed between the CGL2 1190 and the EML3 1230, a third hole transport layer (HTL3) 1220 disposed between the EML3 1230 and the second electrode 620A, and a hole injection layer (HIL) 1210 disposed between the HTL3 1220 and the second electrode 620A. Alternatively, or additionally, the third emitting part 1200 can further include at least one of a third hole blocking layer (HBL3) disposed between the ETL3 1270 and the EML3 1230 and a third electron blocking layer (EBL3) disposed between the EML3 1230 and the HTL3 1220.

In one embodiment, one or two of the EML1 1030, the EML2 1130 and the EML3 1230 emits blue color light and another of the EML1 1030, the EML2 1130 and the EML3 1230 emits red to green color light, so that the OLED D4 can implement white (W) color emission. Hereinafter, the OLED D4 where the EML1 1030 and the EML3 1230 emits blue color light and the EML2 1130 emits red to green color lights will be described in more detail.

The CGL1 1090 is disposed between the first emitting part 1000 and the second emitting part 1100. The CGL1 1090 includes a first P-type charge generation layer (P-CGL1) 1094 disposed between the HTL1 1020 and the ETL2 1170, and a first N-type charge generation layer (N-CGL1) 1092 disposed between the P-CGL1 1094 and the ETL2 1170.

The CGL2 1190 is disposed between the second emitting part 1100 and the third emitting part 1200. The CGL2 1190 includes a second P-type charge generation layer (P-CGL2) 1194 disposed between the HTL2 1120 and the ETL3 1270, and a second N-type charge generation layer (N-CGL2) 1192 disposed between the P-CGL2 1194 and the ETL3 1270.

Each of the N-CGL1 1092 and the N-CGL2 1192 provides electrons to the EML2 1130 of the second emitting part 1100 and the EML3 1230 of the third emitting part 1200, respectively. Each of the P-CGL1 1094 and the P-CGL2 1194 provides holes to the EML1 1030 of the first emitting part 1000 and the EML2 1130 of the second emitting part 1100, respectively.

The materials and contents thereof in the emissive layer 630A can be identical to corresponding materials and contents thereof with referring to FIG. 8 except of the function of the first and second electrodes 610A and 620A and the relative locations of the HIL 1210, the HTLs 1020, 1120 and 1220, the ETLs 1070, 1170 and 1270, the EIL 1080, the N-CGLs 1092 and 1192 and the P-CGLs 1094 and 1194 in the charge generation layers (CGLs) 1090 and 1190.

Each of the EML1 1030 and the EML3 1230 can be a blue emitting material layer (B-EML). In this case, each of the EML1 1030 and the EML3 1230 can be a blue emitting material layer, a sky blue emitting material layer and/or a deep blue emitting material layer. Each of the EML1 1030 and the EML3 1230 can include a blue host and a blue emitter (blue dopant). The blue host can include at least one of a P-type blue host and an N-type blue host. The materials and the contents thereof of the blue host and the blue emitter can be identical to the corresponding material and the contents thereof with referring to FIG. 8.

The EML2 1130 includes a red emitting material layer (R-EML) 1140 disposed between the ETL2 1170 and the HTL2 1120, a green emitting material layer (G-EML) 1150 disposed between the R-EML 1140 and the HTL2 1120 and an exciton control layer (ECL) 1160 disposed between the R-EML 1140 and the G-EML 1150. In another embodiment, the EML2 1130 can further include a yellow-green emitting material layer (YG-EML) disposed between the R-EML 1140 and the ECL 1160 or between the ECL 1160 and the G-EML 1150.

The R-EML 1140 includes a first red host 1142 and/or a second red host 1144, and a red emitter (red dopant) 1146. The first red host 1142 can be a P-type red host and/or the second red host 1144 can be an N-type red host. The G-EML 1150 includes a first green host 1152 and/or a second green host 1154, and a green emitter (green dopant) 1156. The first green host 1152 can be a P-type green host and/or the second green host 1154 can be an N-type green host. The ECL 1160 includes a first compound 1162 and/or a second compound 1164. The materials and the contents thereof in the EML2 1130 can be identical to the corresponding materials and the contents thereof with referring to FIGS. 3, 4 and 6.

In FIGS. 8 and 9, an organic light emitting diode with three emitting parts is described. In another embodiment, the organic light emitting diode with a tandem structure can include two emitting parts, where the third emitting part 900 or 1200 and the CGL2 890 or 1190 are optionally omitted.

The OLEDs D3 and/or D4 with the tandem structure include the ECLs 860 and 1160 between the R-EMLs 840 and 1140 and the G-EMLs 850 and 1150. Exciton recombination zone can be distributed uniformly within the entire area of the EML2 830 or 1130 including the R-EMLs 840 and 1140 and the G-EMLs 850 and 1150. Therefore, the luminous efficiency and the luminous lifetime of the OLEDs D3 and/or D4 can be improved.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Example 1 (Ex. 1): Fabrication of OLED

An organic light emitting diode that includes an exciton control layer between a red emitting material layer and a green emitting material layer was fabricated. A glass substrate onto which ITO (1200 Å) was coated as a thin film was washed and ultrasonically cleaned by solvent such as isopropyl alcohol, acetone and dried at 100° C. oven. The substrate was transferred to a vacuum chamber for depositing emissive layer as the following order:

Electron injection layer (EIL, Bphen (97.5 wt. %), Li (2.5 wt. %), 100 Å); electron transport layer (ETL, ET below, 150 Å); red emitting material layer (R-EML, host (RHH below: REH below=7:3 by weight, 96.5 wt. %), Ir(piq)₂(acac) (3.5 wt. %), 300 Å); exciton control layer (ECL, Compound 1-1 in Chemical Formula 2 (HOMO: −5.62 eV, LUMO: −2.29 eV): Compound 2-1 in Chemical Formula 4 (HOMO: −5.75 eV, LUMO: −3.01 eV)=5:5 by weight, 50 Å); green emitting material layer (G-EML, host (GHH below: GEH below=8:2 by weight, 90 wt. %), Ir(ppy)₂(acac) (10 wt. %), 200 Å); hole transport layer (HTL, HT below (n=1 or 2), 320 Å); hole injection layer (HIL, (HT below (n=1 or 2), 80 wt. %), PD below (20 wt. %), 100 Å); and cathode (Al).

The fabricated OLED was encapsulated with glass and then transferred from the deposition chamber to a dry box in order to form a film. Then the OLED was encapsulated with UV-cured epoxy resin and water getter. The structures of materials of electron injecting material, electron transporting material, hosts, emitters, hole transporting material and hole injection materials are illustrated in the following:

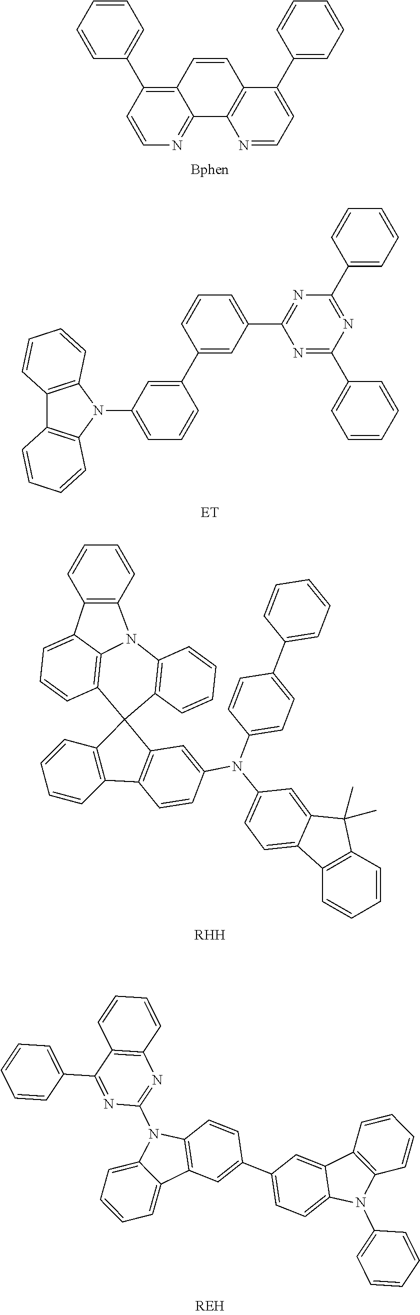 [SMILES: c1ccc(-c2ccnc3c2ccc2c(-c4ccccc4)ccnc23)cc1 ; c1ccc(-c2nc(-c3ccccc3)nc(-c3cccc(-c4cccc(-n5c6ccccc6c6ccccc65)c4)c3)n2)cc1 ; CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; "RHH" ; c1ccc(-c2nc(-n3c4ccccc4c4cc(-c5ccc6c(c5)c5ccccc5n6-c5ccccc5)ccc43)nc3ccccc23)cc1]

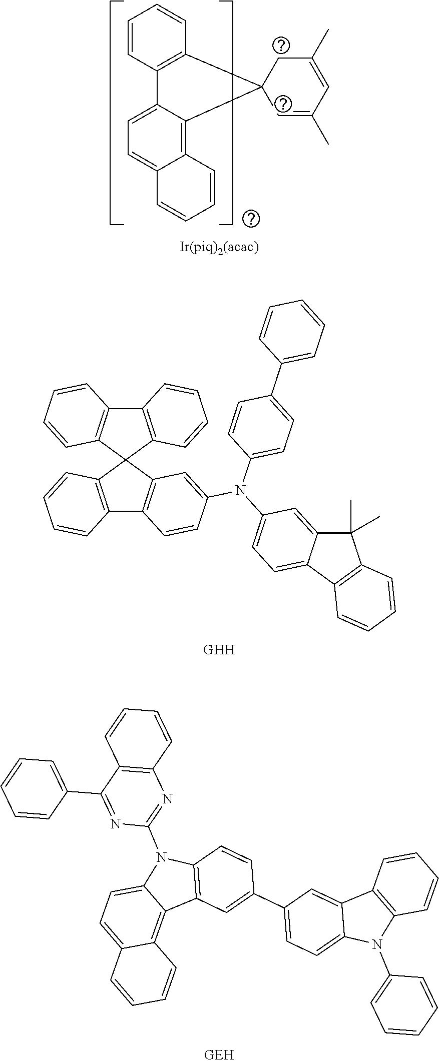

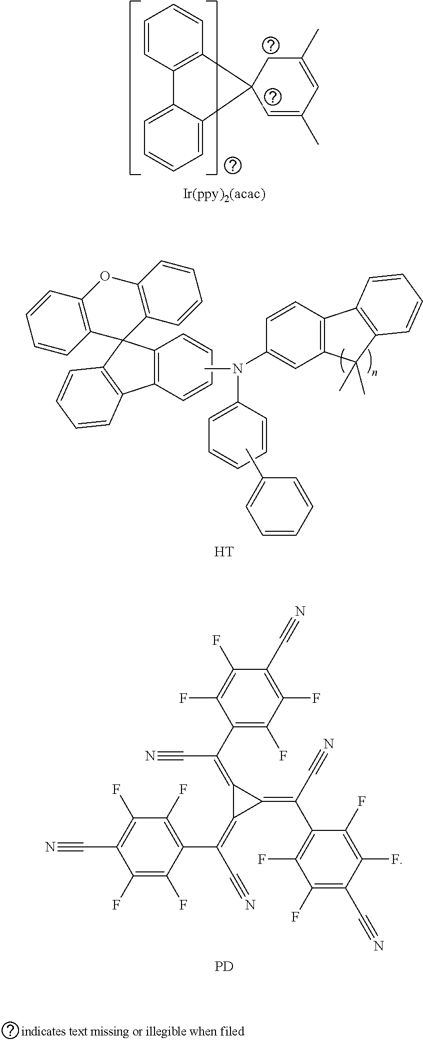

### Example 2 (Ex. 2): Fabrication of OLED

An OLED was fabricated using the same procedure and the same material as Example 1, except that Compound 1-2 in Chemical Formula 2 (HOMO: −5.57 eV, LUMO: −2.51 eV) instead of the Compound 1-1 as the first compound in the ECL and Compound 2-2 in Chemical Formula 4 (HOMO: −5.6 eV, LUMO: −2.87 eV) instead of the Compound 2-1 as the second compound in the ECL were used.

### Example 3 (Ex. 3): Fabrication of OLED

An OLED was fabricated using the same procedure and the same material as Example 1, except that Compound 1-2 in Chemical Formula 2 (HOMO: −5.57 eV, LUMO: −2.51 eV) instead of the Compound 1-1 was used as the first compound in the ECL.

### Comparative Example (Ref.): Fabrication of OLED

An OLED was fabricated using the same procedure and the same material as Example 1, except that the ECL was not disposed between the R-EML and the G-EML.

### Experimental Example 1: Measurement of Luminous Properties of OLEDs

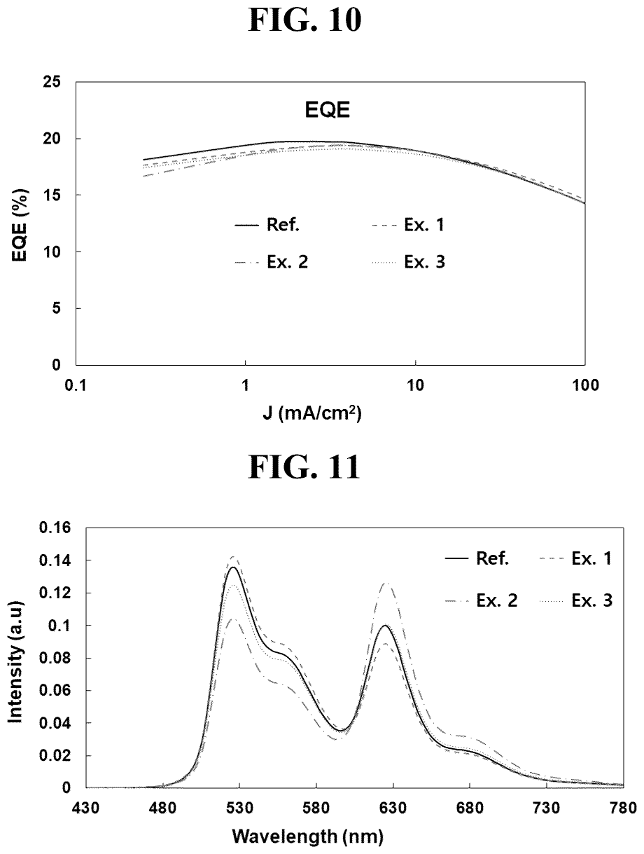

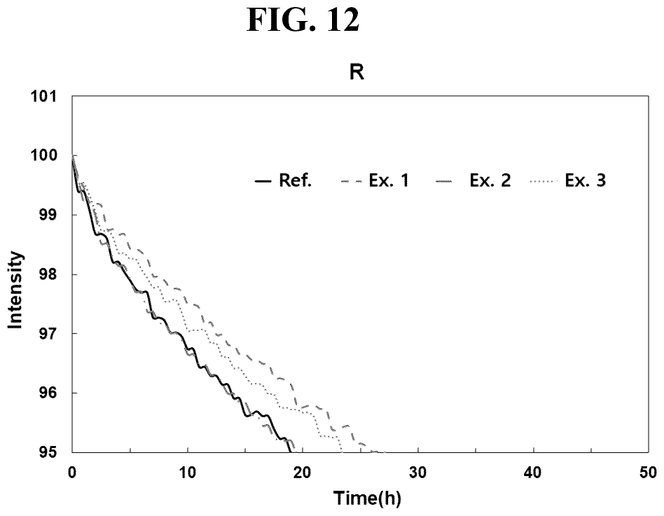

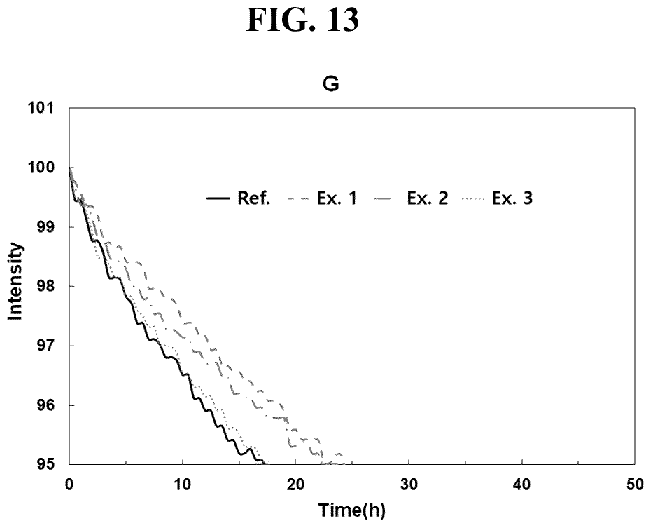

The luminous properties for each of the OLEDs, fabricated in Examples 1 to 3 and Comparative Example, were measured. Each of the OLEDs were connected to an external power source and then luminous properties for all the OLEDs were evaluated using a constant current source (KEITHLEY) and a photometer PR650 at room temperature. In particular, driving voltage (V), current efficiency (cd/A), External quantum efficiency (EQE), color coordinates (CIEx, CIEy), and time period (T95) at which the luminance of the red color light was reduced to 95% from initial luminance of the red light and time period (T95) at which the luminance of the green color light was reduced to 95% from initial luminance of the green light were measure at current density of 10 mA/cm². The measurement results are indicated in the following Table 1 as well as FIGS. 10 to 13.

TABLE 1
Luminous Properties of OLED

| | @10 mA/cm² | | | | | | | |
|---|---|---|---|---|---|---|---|---|
| | | V | | | | | T₉₅ | T₉₅ |
| Sample | V | @100 J | cd/A | EQE | CIEx | CIEy | (Red) | (Green) |
| Ref. | 4.5 | 6.0 | 52.3 | 18.9 | 0.416 | 0.558 | 20 | 17 |
| Ex. 1 | 4.9 | 6.3 | 54.2 | 18.9 | 0.405 | 0.568 | 26 | 23 |
| Ex. 2 | 4.9 | 6.4 | 44.1 | 19.0 | 0.456 | 0.522 | 20 | 24 |
| Ex. 3 | 4.9 | 6.4 | 49.7 | 18.6 | 0.423 | 0.552 | 25 | 17 |

As indicated in Table 1 and FIGS. 10 to 13, compared to the OLED in fabricated in Comparative Example (Ref.), in the OLED fabricated in Examples 1 to 3, the red light luminous lifespan was improved by 30% maximally, and the green light luminous lifespan was improved by 41% maximally.

### Example 4 (Ex. 4): Fabrication of OLED

An OLED was fabricated using the same procedure and the same material as Example 1, except that Compound 1-3 in Chemical Formula 2 (HOMO: −5.69 eV, LUMO: −2.56 eV) instead of the Compound 1-1 was used as the first compound in the ECL.

### Example 5 (Ex. 5): Fabrication of OLED

An OLED was fabricated using the same procedure and the same material as Example 4, except that the thickness of the ECL was modified to 100 Å from 50 Å.

### Experimental Example 2: Measurement of Luminous Properties of OLEDs

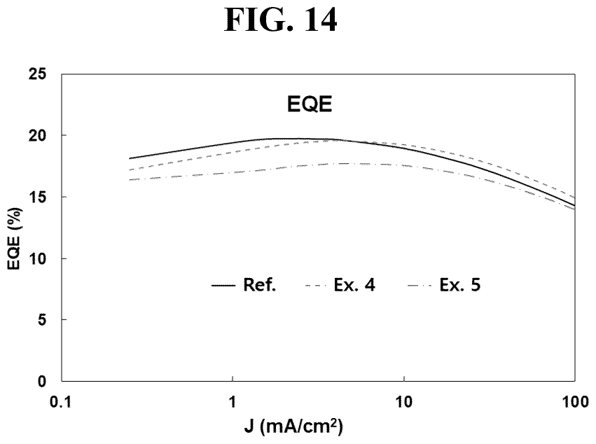

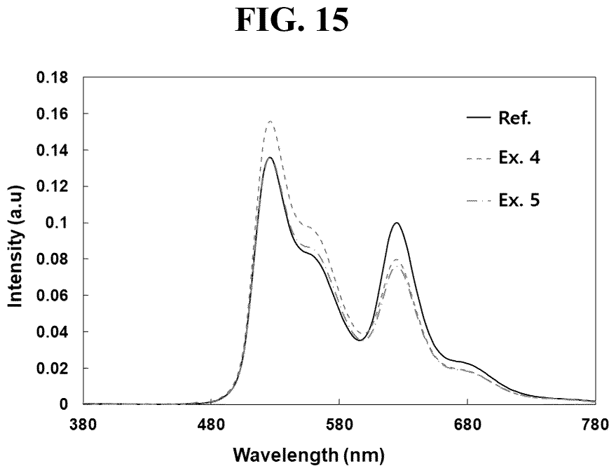

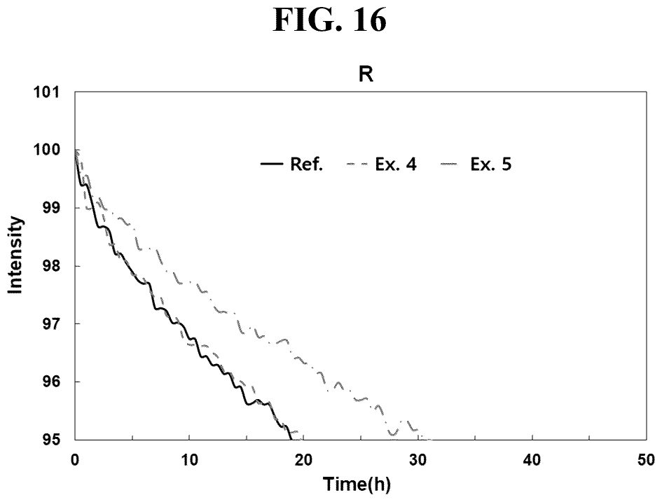

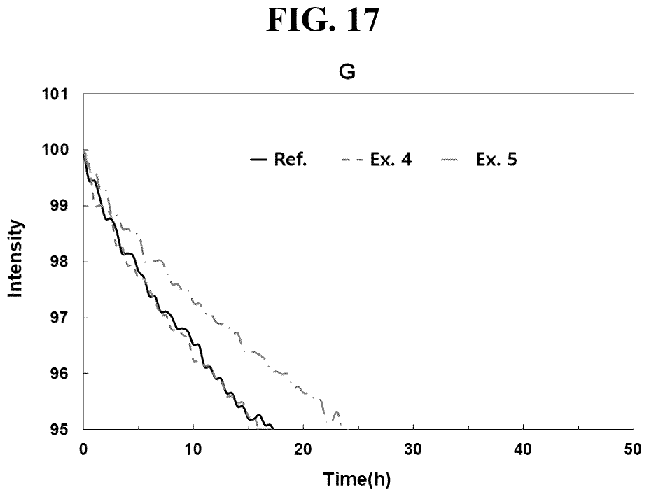

The luminous properties for each of the OLEDs, fabricated in Examples 4 to 5 and Comparative Example, were measured as Experimental Example 1. The measurement results are indicated in the following Table 2 as well as FIGS. 14 to 17.

TABLE 2
Luminous Properties of OLED

| | @10 mA/cm² | | | | | | | |
|---|---|---|---|---|---|---|---|---|
| | | V | | | | | T₉₅ | T₉₅ |
| Sample | V | @100 J | cd/A | EQE | CIEx | CIEy | (Red) | (Green) |
| Ref. | 4.5 | 6.0 | 52.3 | 18.9 | 0.416 | 0.558 | 20 | 17 |
| Ex. 4 | 4.9 | 6.4 | 58.2 | 19.2 | 0.394 | 0.579 | 20 | 16 |
| Ex. 5 | 5.1 | 6.6 | 51.8 | 17.7 | 0.399 | 0.573 | 31 | 24 |

As indicated in Table 2 and FIGS. 14 to 17, compared to the OLED in fabricated in Comparative Example, in the OLED fabricated in Examples 4 to 5, the red light luminous lifespan was improved by 55% maximally, the green light luminous lifespan was improved by 41% maximally, and current efficiency was improved by 11.3% maximally.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode, comprising:
a first electrode;
a second electrode facing the first electrode; and
an emissive layer disposed between the first and second electrode, and comprising an emitting material layer,
wherein the emitting material layer comprises:
a red emitting material layer;
a green emitting material layer disposed between the red emitting material layer and the second electrode; and
an exciton control layer disposed between the red emitting material layer and the green emitting material layer, and
wherein the exciton control layer comprises at least one of a first compound having the following structure of Chemical Formula 1 and a second compound having the following structure of Chemical Formula 3: 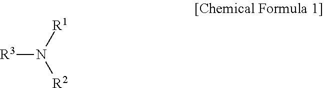
wherein, in Chemical Formula 1,
each of R¹, R² and R³ is independently an unsubstituted or substituted C₆-C₃₀ aryl group or an unsubstituted or substituted C₃-C₃₀ hetero aryl group, 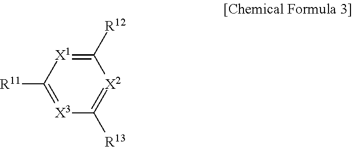
wherein, in Chemical Formula 3,
each of R¹¹, R¹² and R¹³ is independently hydrogen, an unsubstituted or substituted C₆-C₃₀ aryl group or an unsubstituted or substituted C₃-C₃₀ hetero aryl group, where at least one of R¹¹, R¹² and R¹³ has a moiety of the following structure of Chemical Formula 3A;
each of X¹, X² and X³ is independently CR¹⁴ or N, where at least two of X¹, X² and X³ is N;
R¹⁴ is hydrogen, and unsubstituted or substituted C₆-C₃₀ aryl group or an unsubstituted or substituted C₃-C₃₀ hetero aryl group, or
optionally,
adjacent R¹¹ and R¹⁴, adjacent R¹² and R¹⁴ and/or adjacent R¹³ and R¹⁴ are further linked together to form an unsubstituted or substituted C₆-C₂₀ aromatic ring, 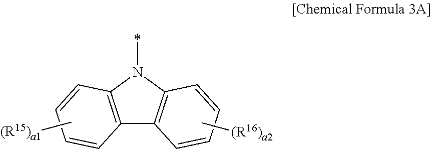
wherein, in Chemical Formula 3A,
each of R¹⁵ and R¹⁶ is independently an unsubstituted or substituted C₆-C₃₀ aryl group or an unsubstituted or substituted C₃-C₃₀ hetero aryl group, where each R¹⁵ is identical to or different from each other when a1 is 2, 3 or 4, and each R¹⁶ is identical to or different from each other when a2 is 2, 3 or 4, or
optionally,
two adjacent R¹⁵ when a1 is 2, 3 or 4, and/or
two adjacent R¹⁶ when a2 is 2, 3 or 4
are further linked together to form an unsubstituted or substituted C₆-C₂₀ aromatic ring;
each of a1 and a2 is independently 0, 1, 2, 3 or 4, where at least one of a1 and a2 is not 0; and
the asterisk indicates a link to a ring of Chemical Formula 3.

2. The organic light emitting diode of claim 1, wherein the exciton control layer comprises the first compound and the second compound.

3. The organic light emitting diode of claim 1, wherein a difference between a highest occupied molecular orbital (HOMO) energy level of the first compound and a HOMO energy level of the second compound is equal to or less than about 0.2 eV.

4. The organic light emitting diode of claim 1, wherein a difference between a highest occupied molecular orbital (HOMO) energy level of the first compound and a HOMO energy level of the second compound is equal to or less than about 0.15 eV.

5. The organic light emitting diode of claim 1, wherein the first compound comprises at least one of the following organic compounds:

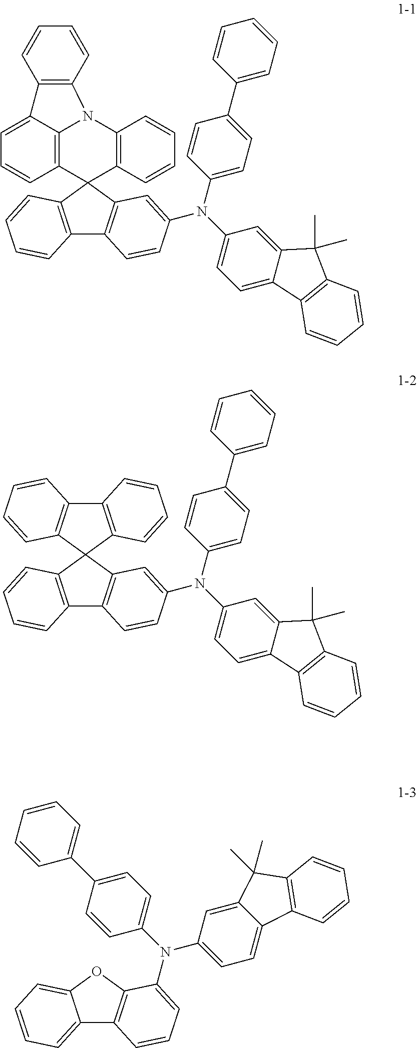 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3cccc4c3oc3ccccc34)cc21]

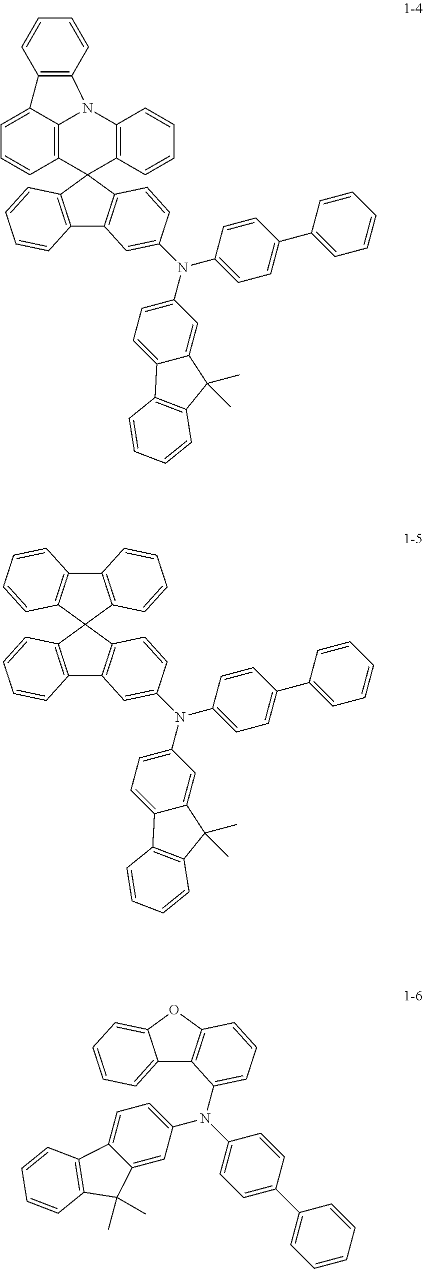 [SMILES: CC1(C)c2ccccc2-c2ccc(N(c3ccc(-c4ccccc4)cc3)c3ccc4c(c3)-c3ccccc3C43c4ccccc4-n4c5ccccc5c5cccc3c54)cc21 ; CC1(C)c2ccccc2-c2ccc(N(c3ccc(-c4ccccc4)cc3)c3ccc4c(c3)-c3ccccc3C43c4ccccc4-c4ccccc43)cc21 ; CC1(C)c2ccccc2-c2ccc(N(c3ccc(-c4ccccc4)cc3)c3cccc4oc5ccccc5c34)cc21]

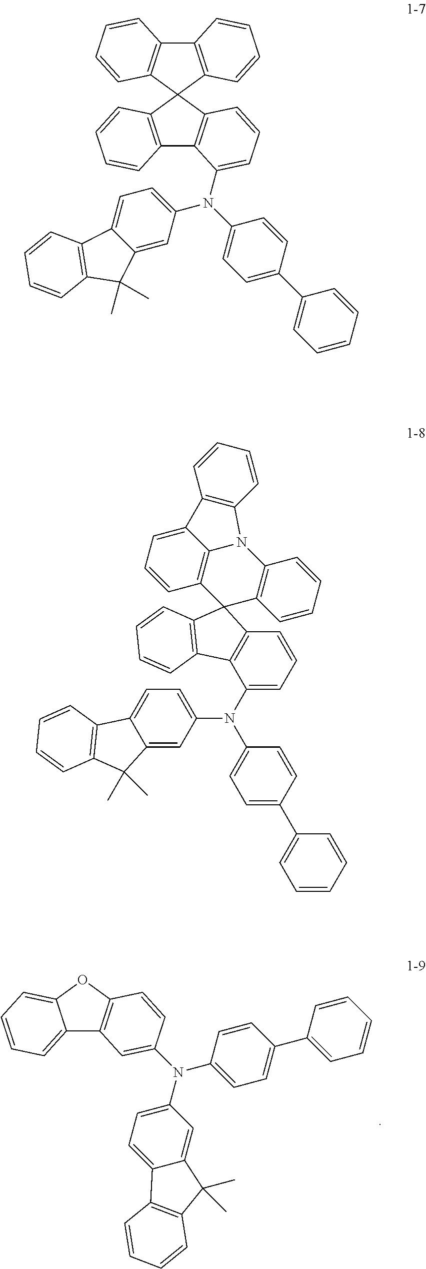 [SMILES: CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-n4c5ccccc5c5cccc3c54)cc21 ; CC1(C)c2ccccc2-c2ccc(N(c3ccc(-c4ccccc4)cc3)c3ccc4oc5ccccc5c4c3)cc21]

6. The organic light emitting diode of claim 1, wherein the second compound comprises at least one of the following compounds:

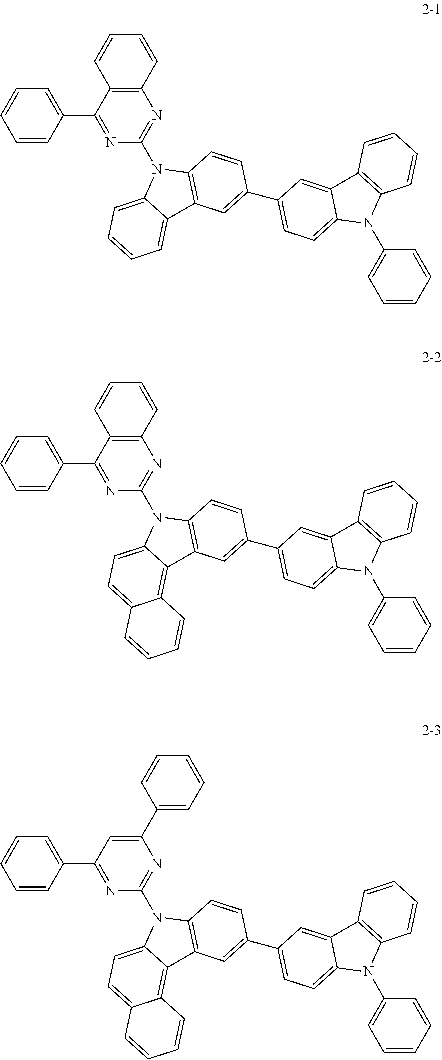 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2cc(-c3ccccc3)nc(-n3c4ccc(-c5ccc6c(c5)c5ccccc5n6-c5ccccc5)cc4c4c5ccccc5ccc43)n2)cc1]

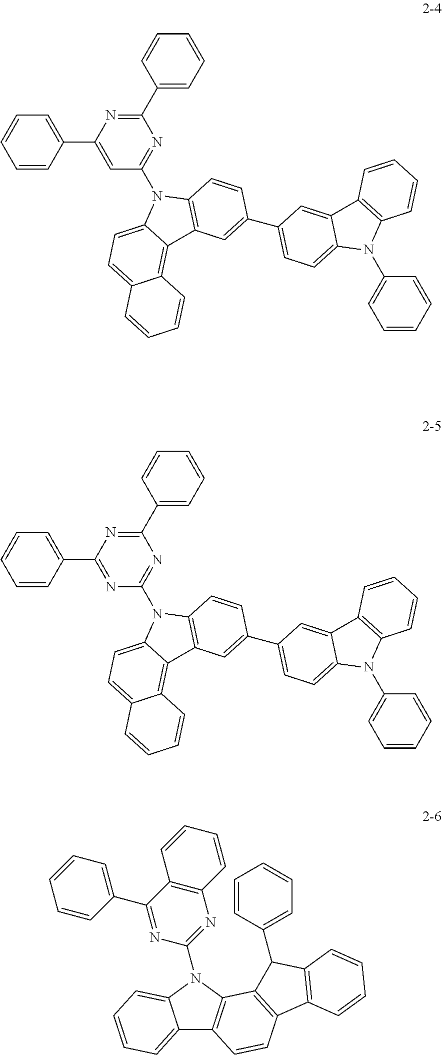 [SMILES: c1ccc(-c2cc(-n3c4ccc(-c5ccc6c(c5)c5ccccc5n6-c5ccccc5)cc4c4c5ccccc5ccc43)nc(-c3ccccc3)n2)cc1 ; c1ccc(-c2nc(-c3ccccc3)nc(-n3c4ccc(-c5ccc6c(c5)c5ccccc5n6-c5ccccc5)cc4c4c5ccccc5ccc43)n2)cc1 ; c1ccc(-c2nc(-n3c4ccccc4c4ccc5c(c43)C(c3ccccc3)c3ccccc3-5)nc3ccccc23)cc1]

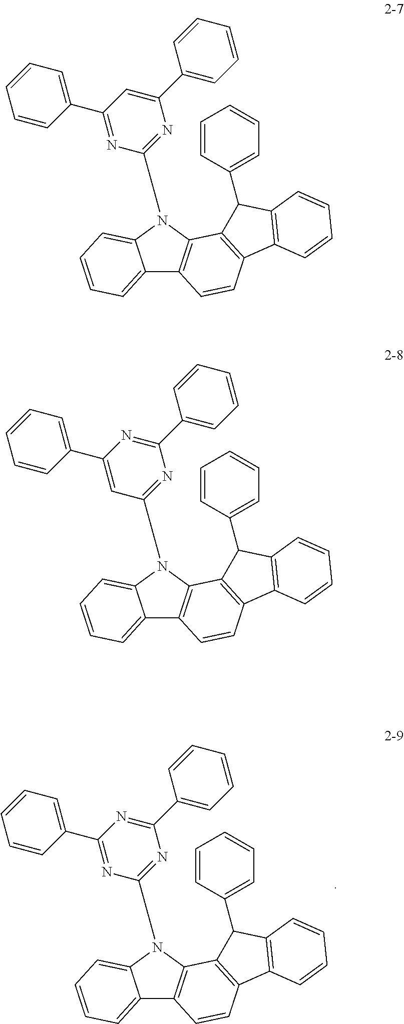 [SMILES: c1ccc(-c2cc(-c3ccccc3)nc(-n3c4ccccc4c4ccc5c(c43)C(c3ccccc3)c3ccccc3-5)n2)cc1 ; c1ccc(-c2cc(-n3c4ccccc4c4ccc5c(c43)C(c3ccccc3)c3ccccc3-5)nc(-c3ccccc3)n2)cc1 ; c1ccc(-c2nc(-c3ccccc3)nc(-n3c4ccccc4c4ccc5c(c43)C(c3ccccc3)c3ccccc3-5)n2)cc1]

7. The organic light emitting diode of claim 1, wherein the first compound and the second compound in the exciton control layer are mixed with a weight ratio in a range between about 7:3 and about 3:7.

8. The organic light emitting diode of claim 1, wherein the emissive layer further comprises:
an electron transport layer disposed between the first electrode and the emitting material layer; and
a hole transport layer disposed between the emitting material layer and the second electrode.

9. The organic light emitting diode of claim 1, wherein the emissive layer comprises:
a first emitting part disposed between the first electrode and the second electrode, and comprising a first emitting material layer;
a second emitting part disposed between the first emitting part and the second electrode, and comprising a second emitting material layer, and
a first charge generation layer disposed between the first emitting part and the second emitting part.

10. The organic light emitting diode of claim 9, wherein the second emitting part comprises the red emitting material layer, the green emitting material layer and the exciton control layer.

11. The organic light emitting diode of claim 9, wherein the emissive layer further comprises:
a third emitting part disposed between the second emitting part and the second electrode, and comprising a third emitting material layer; and
a second charge generation layer disposed between the second emitting part and the third emitting part.

12. An organic light emitting diode, comprising:
a first electrode;
a second electrode facing the first electrode; and
an emissive layer disposed between the first electrode and the second electrode,
wherein the emissive layer comprises:
a first emitting part disposed between the first electrode and the second electrode, and comprising a first emitting material layer;
a second emitting part disposed between the first emitting part and the second electrode, and comprising a second emitting material layer; and
a first charge generation layer disposed between the first emitting part and the second emitting part,
wherein the first emitting part comprises a first blue emitting material layer,
wherein the second emitting part comprises:
a red emitting material layer disposed between the first charge generation layer and the second electrode;
a green emitting material layer disposed between the red emitting material layer and the second electrode; and
an exciton control layer disposed between the red emitting material layer and the green emitting material layer, and
wherein the exciton control layer comprises at least one of a first compound having the following structure of Chemical Formula 1 and a second compound having the following structure of Chemical Formula 3: 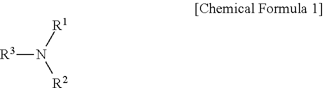
wherein, in Chemical Formula 1,
each of R¹, R² and R³ is independently an unsubstituted or substituted C₆-C₃₀ aryl group or an unsubstituted or substituted C₃-C₃₀ hetero aryl group, 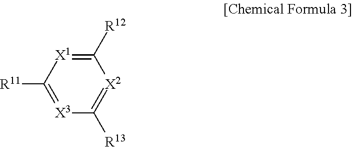
wherein, in Chemical Formula 3,
each of R¹¹, R¹² and R¹³ is independently hydrogen, an unsubstituted or substituted C₆-C₃₀ aryl group or an unsubstituted or substituted C₃-C₃₀ hetero aryl group, where at least one of R¹¹, R¹² and R¹³ has a moiety of the following structure of Chemical Formula 3A;
each of X¹, X² and X³ is independently CR¹⁴ or N, where at least two of X¹, X² and X³ is N;
R¹⁴ is hydrogen, and unsubstituted or substituted C₆-C₃₀ aryl group or an unsubstituted or substituted C₃-C₃₀ hetero aryl group, or
optionally,
adjacent R¹¹ and R¹⁴, adjacent R¹² and R¹⁴ and/or adjacent R¹³ and R¹⁴ are further linked together to form an unsubstituted or substituted C₆-C₂₀ aromatic ring, 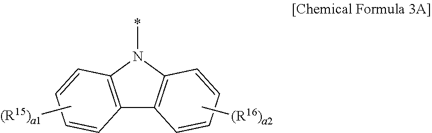
wherein, in Chemical Formula 3A,
each of R¹⁵ and R¹⁶ is independently an unsubstituted or substituted C₆-C₃₀ aryl group or an unsubstituted or substituted C₃-C₃₀ hetero aryl group, where each R¹⁵ is identical to or different from each other when a1 is 2, 3 or 4, and each R¹⁶ is identical to or different from each other when a2 is 2, 3 or 4, or
optionally,
two adjacent R¹⁵ when a1 is 2, 3 or 4, and/or
two adjacent R¹⁶ when a2 is 2, 3 or 4 are further linked together to form an unsubstituted or substituted C₆-C₂₀ aromatic ring;
each of a1 and a2 is independently 0, 1, 2, 3 or 4, where at least one of a1 and a2 is not 0; and
the asterisk indicates a link to a ring of Chemical Formula 3.

13. The organic light emitting diode of claim 12, wherein the exciton control layer comprises the first compound and the second compound.

14. The organic light emitting diode of claim 12, wherein a difference between a highest occupied molecular orbital (HOMO) energy level of the first compound and a HOMO energy level of the second compound is equal to or less than about 0.2 eV.

15. The organic light emitting diode of claim 12, wherein a difference between a highest occupied molecular orbital (HOMO) energy level of the first compound and a HOMO energy level of the second compound is equal to or less than about 0.15 eV.

16. The organic light emitting diode of claim 12, wherein the first compound comprises at least one of the following organic compounds:

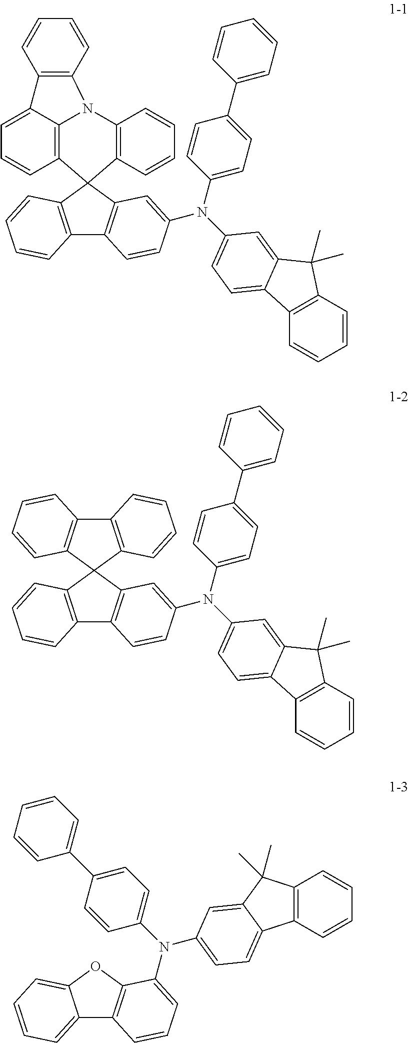 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3cccc4c3oc3ccccc34)cc21]

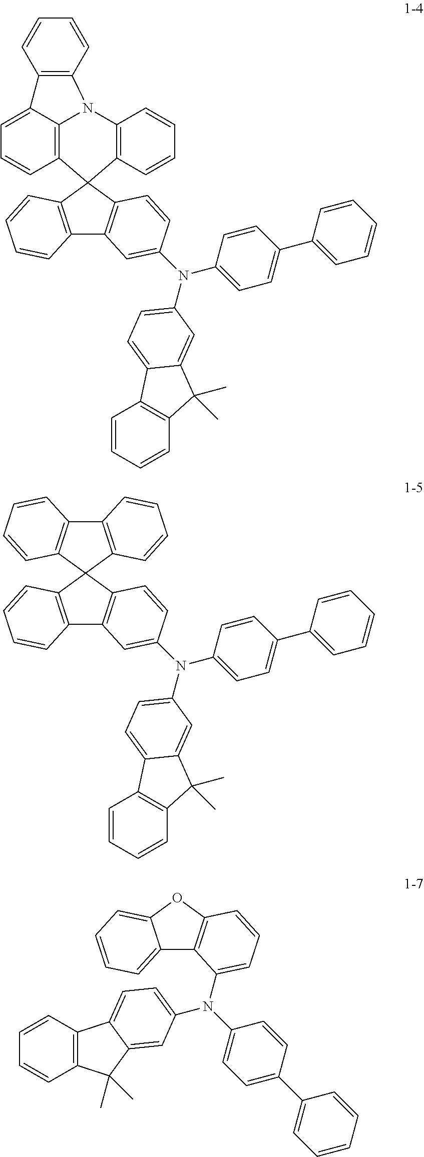

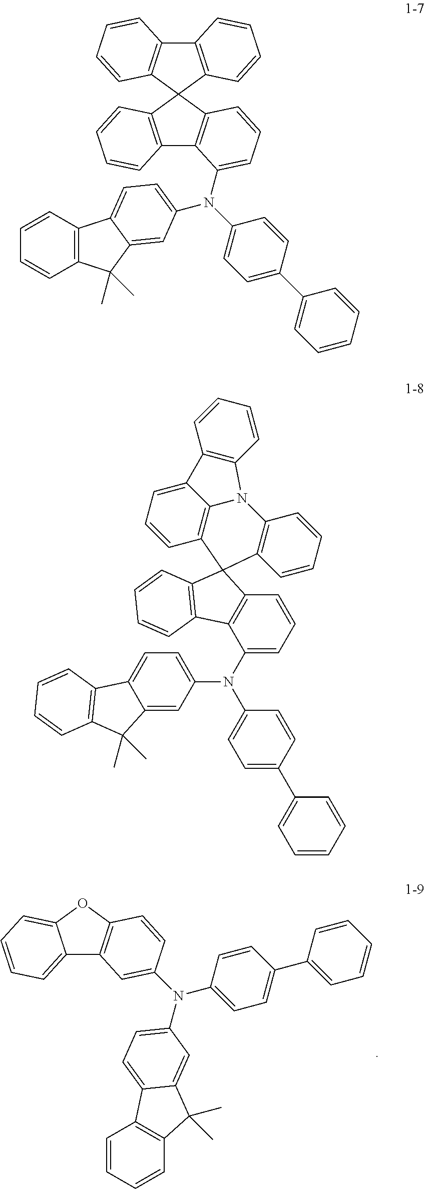 [SMILES: CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-n4c5ccccc5c5cccc3c54)cc21 ; CC1(C)c2ccccc2-c2ccc(N(c3ccc(-c4ccccc4)cc3)c3ccc4oc5ccccc5c4c3)cc21]

17. The organic light emitting diode of claim 12, wherein the second compound comprises at least one of the following compounds:

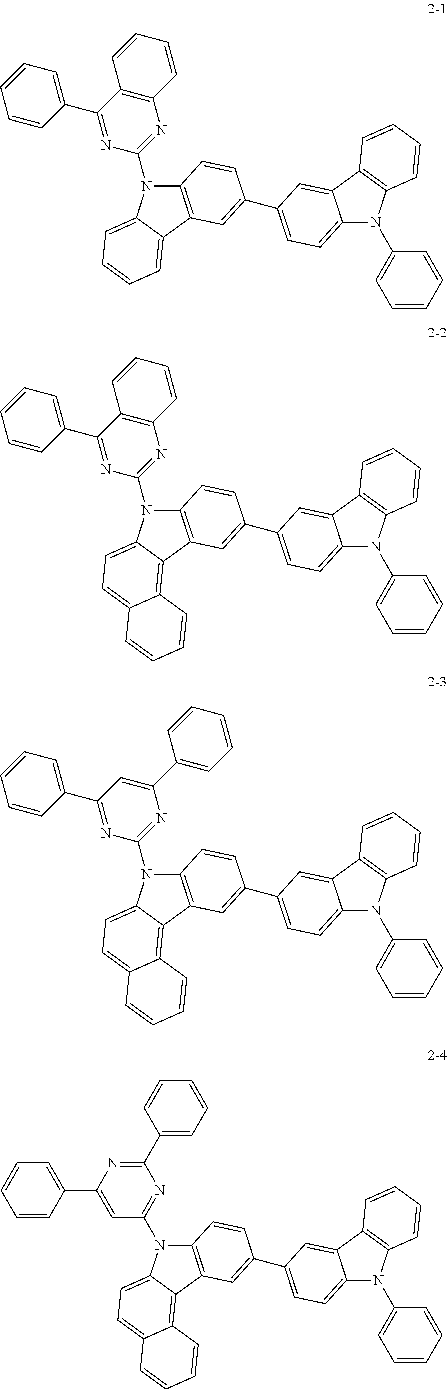 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2cc(-c3ccccc3)nc(-n3c4ccc(-c5ccc6c(c5)c5ccccc5n6-c5ccccc5)cc4c4c5ccccc5ccc43)n2)cc1 ; c1ccc(-c2cc(-n3c4ccc(-c5ccc6c(c5)c5ccccc5n6-c5ccccc5)cc4c4c5ccccc5ccc43)nc(-c3ccccc3)n2)cc1]

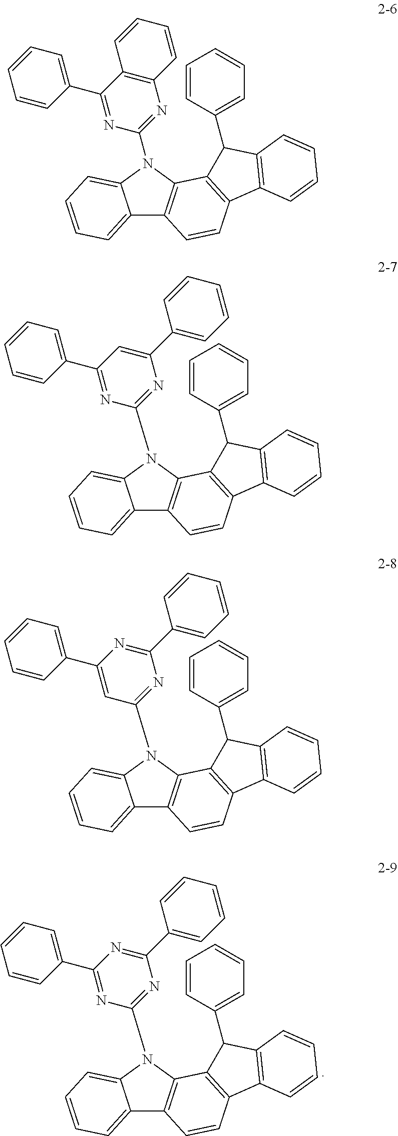

18. The organic light emitting diode of claim 12, wherein the first compound and the second compound in the exciton control layer are mixed with a weight ratio in a range between about 7:3 and about 3:7.

19. The organic light emitting diode of claim 1, wherein the second emitting part further comprises:
an electron transport layer disposed between the first charge generation layer and the second emitting material layer; and
a hole transport layer disposed between the second emitting material layer and the second electrode.

20. The organic light emitting diode of claim 12, wherein the emissive layer comprises:
a third emitting part disposed between the second emitting part and the second electrode, and comprising a third emitting material layer; and
a second charge generation layer disposed between the second emitting part and the third emitting part, and
wherein the third emitting material layer comprises a second blue emitting material layer.

21. A display device comprising:
a display panel configured to display an image and including a plurality of pixels,
wherein each of at least one of the plurality of pixels includes the organic light emitting diode of claim 1.

22. An organic light emitting diode, comprising:
a first electrode;
a second electrode facing the first electrode; and
an emissive layer disposed between the first and second electrode, and comprising an emitting material layer,
wherein the emitting material layer comprises:
a red emitting material layer;
a green emitting material layer disposed between the red emitting material layer and the second electrode; and
an exciton control layer disposed between the red emitting material layer and the green emitting material layer, and
wherein the exciton control layer comprises a first compound having the following structure of Chemical Formula 1 and/or a second compound having the following structure of Chemical Formula 3: 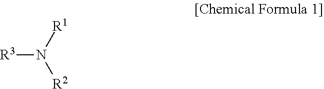
wherein, in Chemical Formula 1,
each of R¹, R² and R³ is independently an unsubstituted or substituted phenyl, biphenyl, 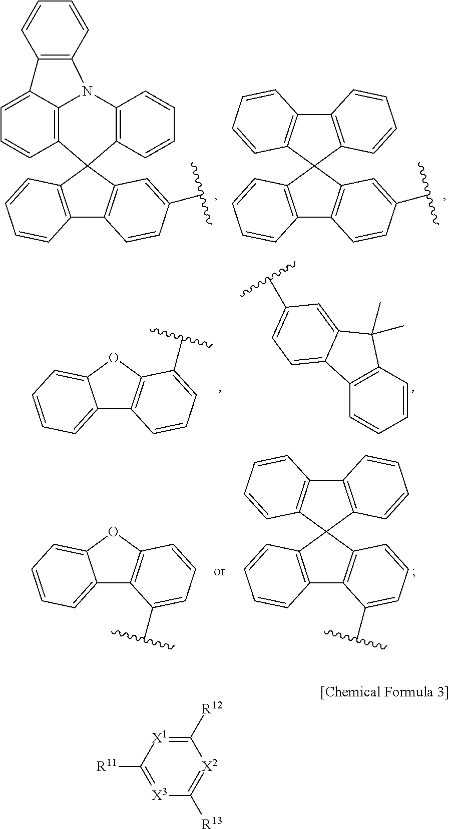
wherein, in Chemical Formula 3,
each of R¹¹, R¹² and R¹³ is independently an unsubstituted or substituted phenyl, biphenyl,

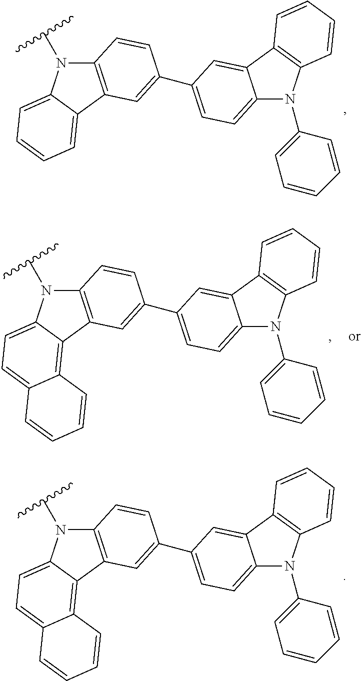

23. The organic light emitting diode of claim 22, wherein the first compound comprises at least one of the following organic compounds: 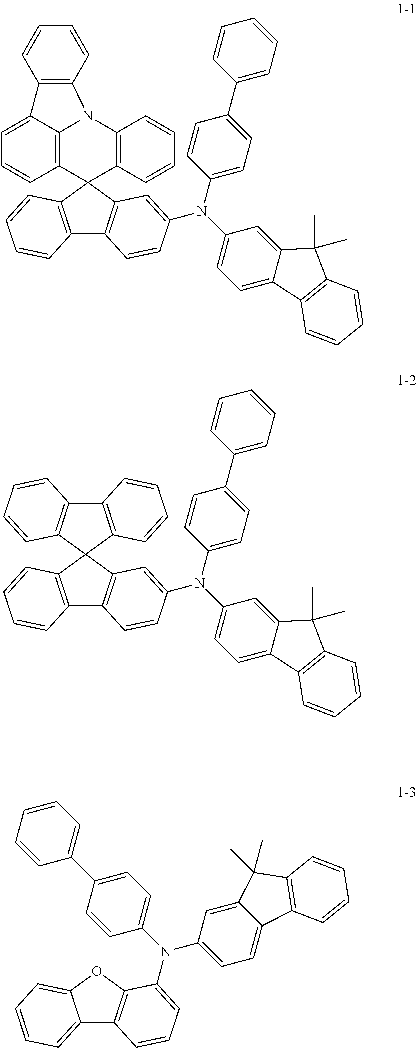 [SMILES: CC1(C)c2ccccc2-c2ccc(N(c3ccc(-c4ccccc4)cc3)c3ccc4c(c3)C3(c5ccccc5-4)c4ccccc4-n4c5ccccc5c5cccc3c54)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3cccc4c3oc3ccccc34)cc21] 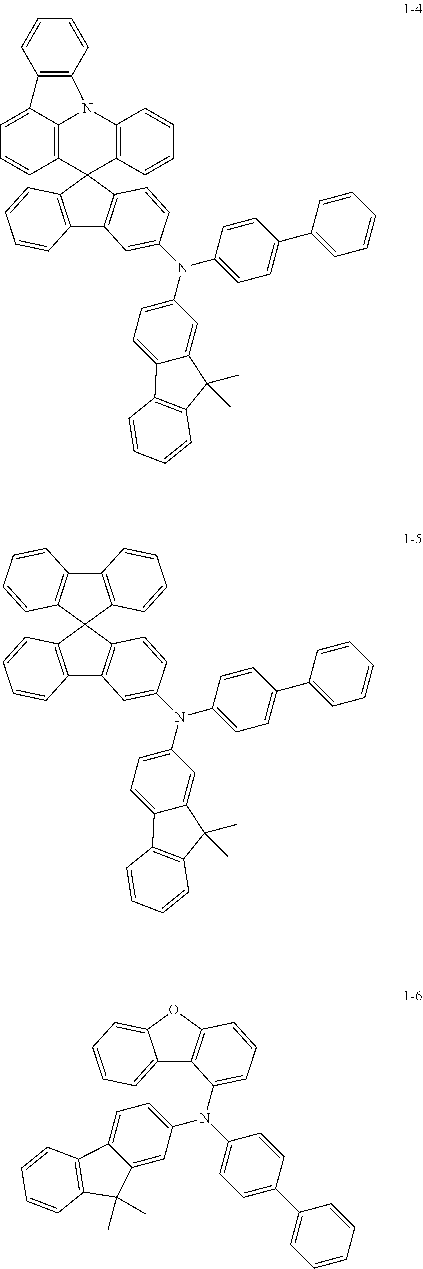 [SMILES: CC1(C)c2ccccc2-c2ccc(N(c3ccc(-c4ccccc4)cc3)c3ccc4c(c3)-c3ccccc3C43c4ccccc4-n4c5ccccc5c5cccc3c54)cc21 ; CC1(C)c2ccccc2-c2ccc(N(c3ccc(-c4ccccc4)cc3)c3ccc4c(c3)-c3ccccc3C43c4ccccc4-c4ccccc43)cc21 ; CC1(C)c2ccccc2-c2ccc(N(c3ccc(-c4ccccc4)cc3)c3cccc4oc5ccccc5c34)cc21] 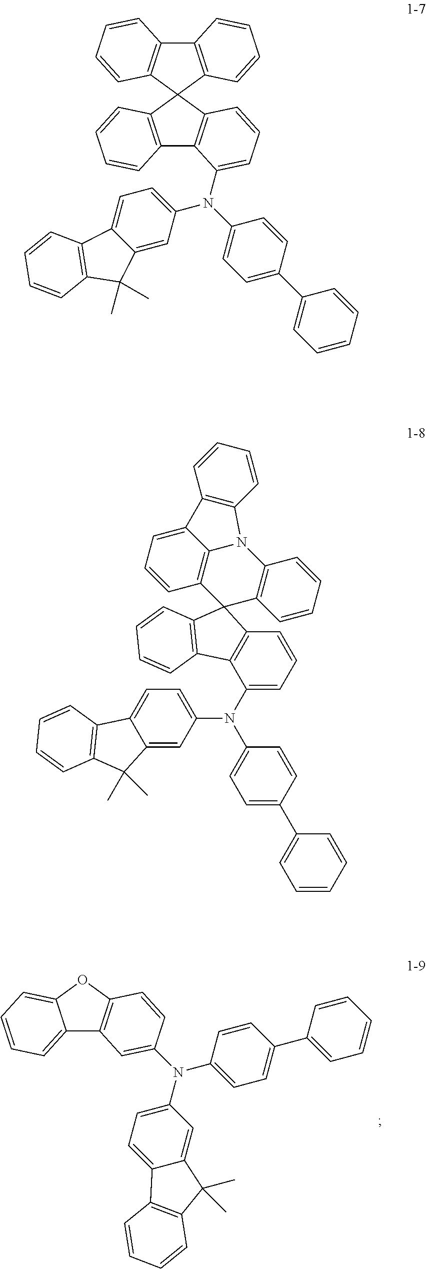 [SMILES: CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-n4c5ccccc5c5cccc3c54)cc21 ; CC1(C)c2ccccc2-c2ccc(N(c3ccc(-c4ccccc4)cc3)c3ccc4oc5ccccc5c4c3)cc21]
and the second compound comprises at least one of the following compounds:

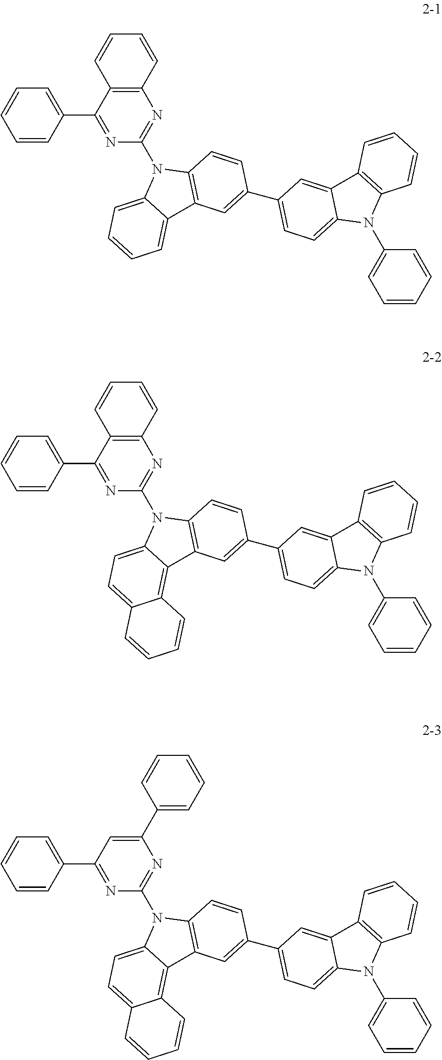 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2cc(-c3ccccc3)nc(-n3c4ccc(-c5ccc6c(c5)c5ccccc5n6-c5ccccc5)cc4c4c5ccccc5ccc43)n2)cc1]

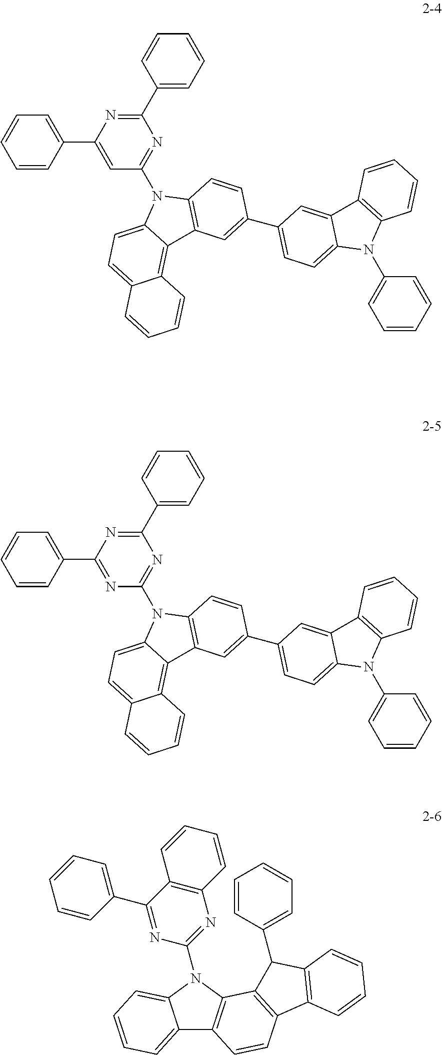 [SMILES: c1ccc(-c2cc(-n3c4ccc(-c5ccc6c(c5)c5ccccc5n6-c5ccccc5)cc4c4c5ccccc5ccc43)nc(-c3ccccc3)n2)cc1 ; c1ccc(-c2nc(-c3ccccc3)nc(-n3c4ccc(-c5ccc6c(c5)c5ccccc5n6-c5ccccc5)cc4c4c5ccccc5ccc43)n2)cc1 ; c1ccc(-c2nc(-n3c4ccccc4c4ccc5c(c43)C(c3ccccc3)c3ccccc3-5)nc3ccccc23)cc1]

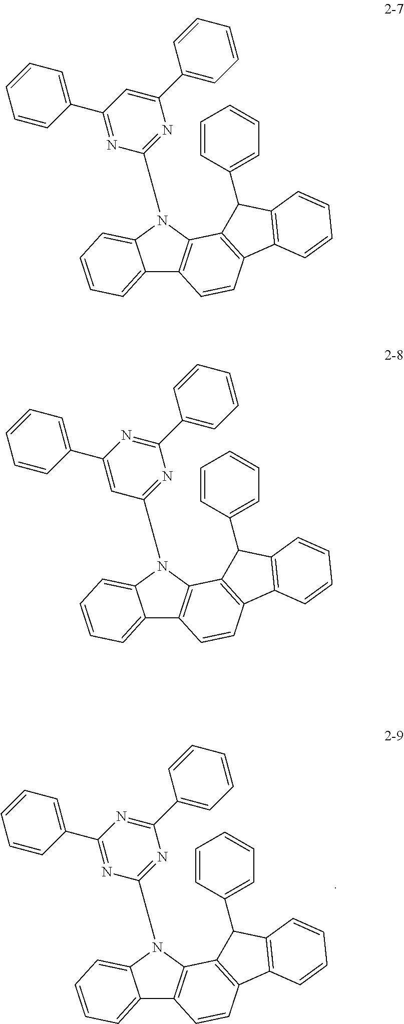 [SMILES: c1ccc(-c2cc(-c3ccccc3)nc(-n3c4ccccc4c4ccc5c(c43)C(c3ccccc3)c3ccccc3-5)n2)cc1 ; c1ccc(-c2cc(-n3c4ccccc4c4ccc5c(c43)C(c3ccccc3)c3ccccc3-5)nc(-c3ccccc3)n2)cc1 ; c1ccc(-c2nc(-c3ccccc3)nc(-n3c4ccccc4c4ccc5c(c43)C(c3ccccc3)c3ccccc3-5)n2)cc1]

24. A display device comprising:
a display panel configured to display an image and including a plurality of pixels,
wherein each of at least one of the plurality of pixels includes the organic light emitting diode of claim 22.
